(19) United States
(12) Patent Application Publication
(10) Pub. No.: US 2025/0374623 A1
(43) Pub. Date: Dec. 4, 2025

(54) SEMICONDUCTOR DEVICE AND METHOD OF FORMING THEREOF

(71) Applicant: TAIWAN SEMICONDUCTOR MANUFACTURING COMPANY, LTD., Hsinchu (TW)

(72) Inventors: Han-Yu TANG, Hsinchu (TW); Chih-Chiang CHANG, Hsinchu County (TW); Ming-Hua YU, Hsinchu City (TW)

(73) Assignee: TAIWAN SEMICONDUCTOR MANUFACTURING COMPANY, LTD., Hsinchu (TW)

(21) Appl. No.: 18/731,031

(22) Filed: May 31, 2024

(51) Int. Cl. H01L 29/08; H01L 21/8238; H01L 27/092; H01L 29/06; H01L 29/66; H01L 29/775; H01L 29/78; H01L 29/786

(52) U.S. Cl. CPC H10D 62/151; H10D 30/014; H10D 30/024; H10D 30/43; H10D 30/6211; H10D 30/6757; H10D 62/121; H10D 84/017; H10D 84/0193; H10D 84/038; H10D 84/853

(57) ABSTRACT

A method of forming a semiconductor device includes a number of operations. Source/drain recesses are formed on opposing side of a channel region over a substrate. Anti-doping epitaxial layers are formed over the source/drain recesses, wherein the anti-doping epitaxial layers have a first conductivity type. Source/drain epitaxial regions are formed over the anti-doping epitaxial layers, wherein the source/drain epitaxial regions have a second conductivity type different from the first conductivity type. A gate structure is formed over the channel regions.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of gate-all-around field-effect transistors (GAA-FETs) in a three-dimensional view, in accordance with some embodiments.

FIGS. 2 through 5, 6A, 14A, 15A, 16A, 17A and 18A illustrate reference cross-section A-A′ illustrated in FIG. 1 that extends through a gate region along a longitudinal axis of the gate region.

FIGS. 6B, 7B, 8B, 9B, 10B, 11B, 11C, 12A, 12B, 13B, 13D, 14B, 15B, 16B, 17B, 18B, 19, 20, 21, 22, 23A and 24A through 24C illustrate reference cross-section B-B′ illustrated in FIG. 1 that extends through a fin along a longitudinal axis of the fin.

FIGS. 7A, 8A, 9A, 10A, 11A, 13A, 13C and 14C illustrate reference cross-section C-C′ illustrated in FIG. 1 that extends through source/drain regions along the longitudinal direction of the gate region.

FIGS. 23B through 23D illustrate zoomed-in cross-sectional view of the structure shown in FIG. 23A, in accordance with some embodiments.

FIG. 25 is a perspective view of a Fin Field-Effect Transistor (FinFET), in accordance with some embodiments.

FIGS. 26 through 28, 29B and 33B illustrate cross-sectional views of the FinFET device along cross-section E-E′ of FIG. 25, in accordance with some embodiments.

FIGS. 29A, 30A, 31A, 32A, 33A and 34 illustrate cross-sectional views of the FinFET device along cross-section D-D′ of FIG. 25, in accordance with some embodiments.

FIGS. 29C, 30B, 31B, 32B, 32C and 33C illustrate cross-sectional views of the FinFET device along cross-section F-F′ of FIG. 25, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The present disclosure is generally related to semiconductor device such as integrated circuit (IC) structures and methods of forming the same, and more particularly to fabricating fin field effect transistors (FinFET), and/or gate-all-around (GAA) transistors, planar transistors. It is also noted that the present disclosure presents embodiments in the form of multi-gate transistors. Multi-gate transistors include those transistors whose gate structures are formed on at least two-sides of a channel region. These multi-gate devices may include a p-type metal-oxide-semiconductor device or an n-type metal-oxide-semiconductor device. Specific examples may be presented and referred to herein as FinFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), and/or other suitable channel configuration. Presented herein are embodiments of devices that may have one or more channel regions (e.g., nanosheets) associated with a single, contiguous gate structure. However, one of ordinary skill would recognize that the teaching can apply to a single channel (e.g., single nanosheet) or any number of channels. One of ordinary skill may recognize other examples of semiconductor devices that may benefit from aspects of the present disclosure.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In the semiconductor device of one or more embodiments, since the dopant of the source/drain region may diffuse from the source/drain region to the channel region, the channel region may be unintentionally doped, resulting in unexpected off-state current leakage between the channel region and the source/drain region.

Various embodiments of the present disclosure relate to a semiconductor device including an anti-doping epitaxial layer between channel regions and source/drain regions. The anti-doping epitaxial layer may have different conductivity type from the source/drain regions, which could be either p-type or n-type depending on the desired device characteristics. The primary function of this layer is to induce an abruptness in the junction doping profile. The abrupt doping profile is achieved by preventing the unintended diffusion of dopants from highly doped source/drain regions into the channel regions. The anti-doping epitaxial layer serves as a barrier to dopant migration, thereby preserving the integrity of the channel composition. The resultant abruptness in the junction doping profile allows for lowering channel resistance, which in turn boosting the overall device performance. Moreover, the anti-doping layer is formed using an in-situ or ex-situ epitaxy process without incurring a yield penalty, meaning that the reliability and manufacturability of the semiconductor devices are not compromised due to the additional anti-doping layer.

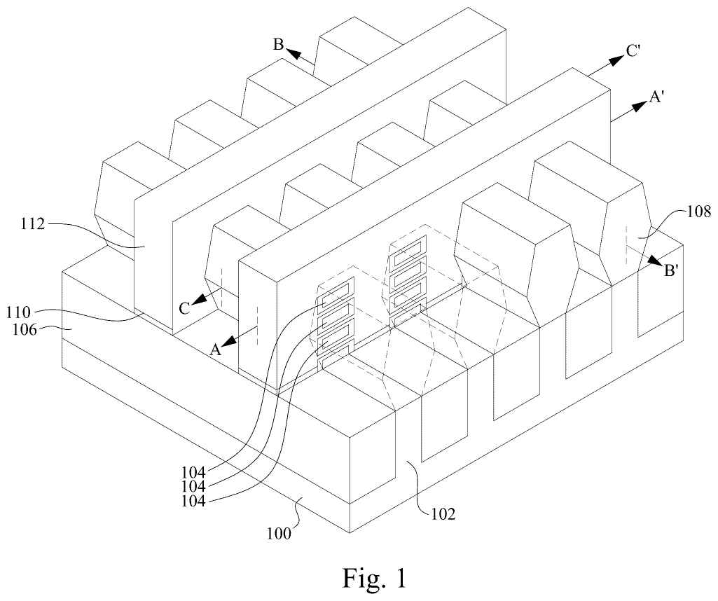

FIG. 1 further illustrates reference cross-sections that are used in later figures. Cross-section A-A′ is along a longitudinal axis of a gate electrode 112 and in a direction, for example, perpendicular to the direction of current flow between the epitaxial source/drain regions 108 of a GAA-FET. Cross-section B-B′ is perpendicular to cross-section A-A′ and is parallel to a longitudinal axis of a fin 102 of the GAA-FET and in a direction of, for example, a current flow between the epitaxial source/drain regions 108 of the GAA-FET. Cross-section C-C′ is parallel to cross-section A-A′ and extends through epitaxial source/drain regions of the GAA-FETs. Subsequent figures refer to these reference cross-sections for clarity.

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs).

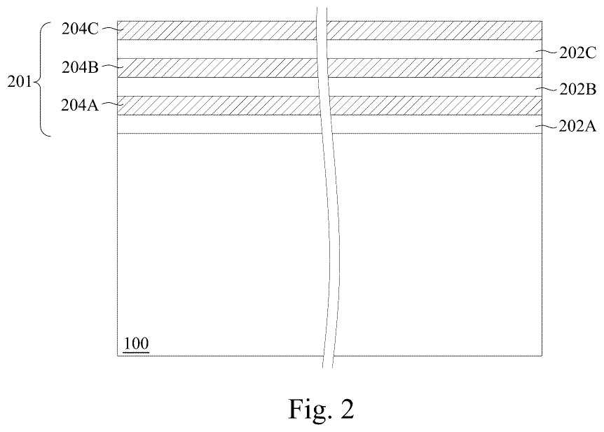

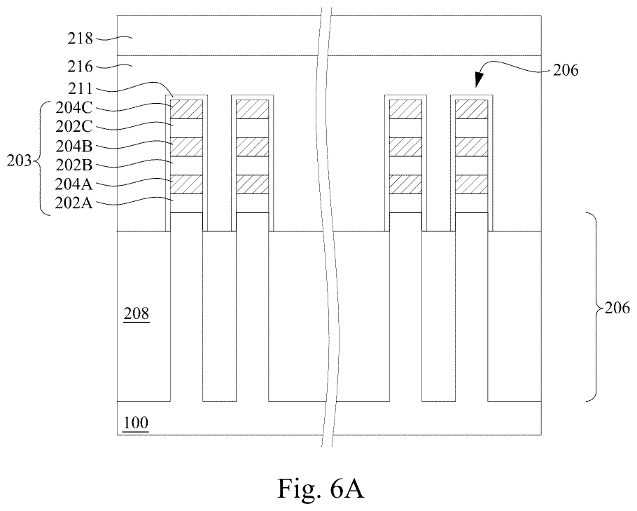

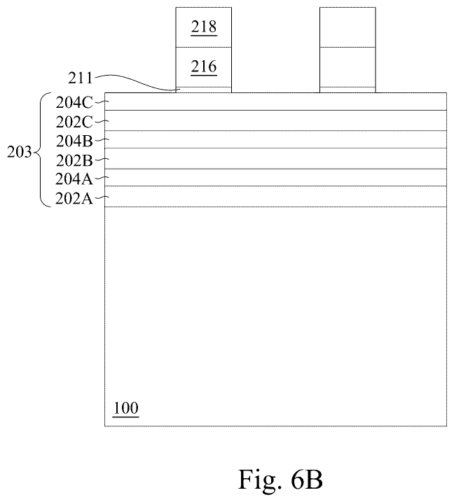

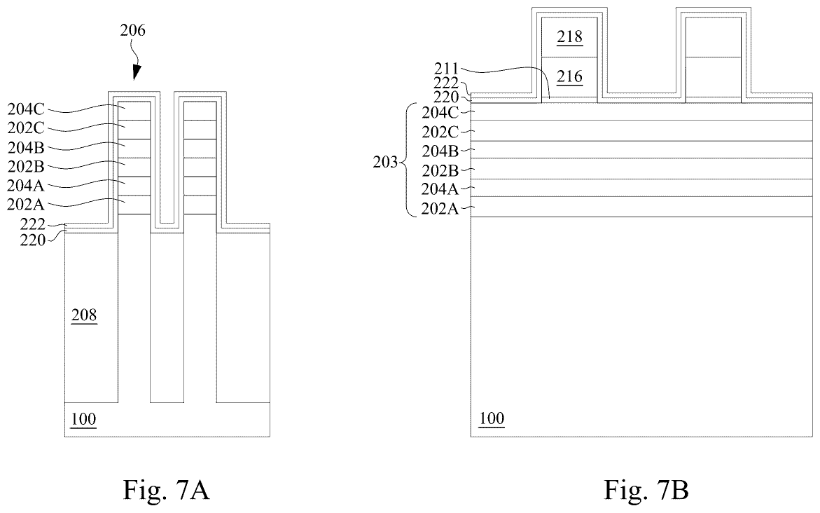

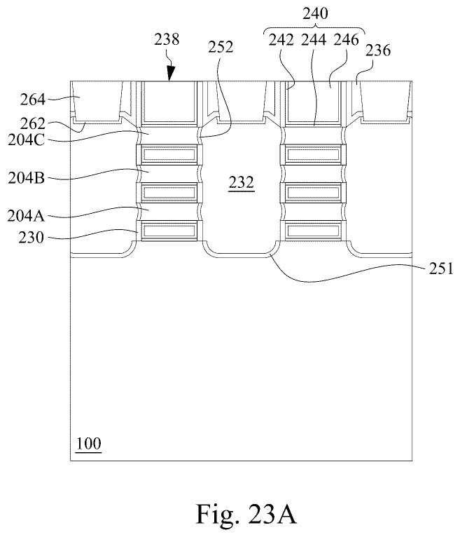

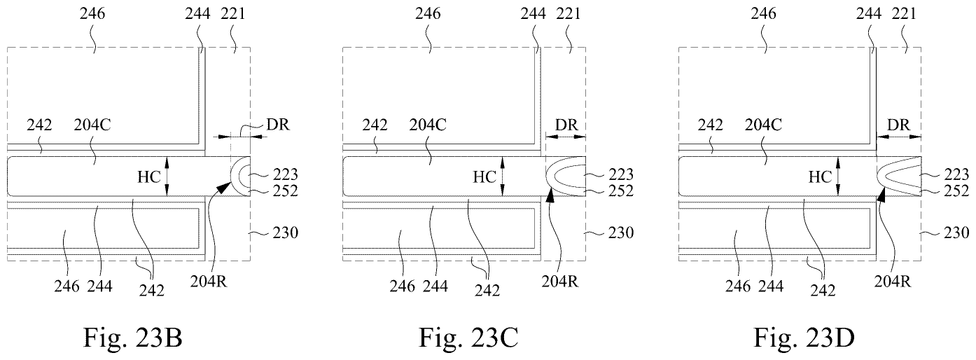

FIGS. 2 through 24C are cross-sectional views and top views of intermediate stages in the manufacturing of GAA-FETs, in accordance with some embodiments. FIGS. 2 through 5, 6A, 14A, 15A, 16A, 17A and 18A illustrate reference cross-section A-A′ illustrated in FIG. 1 that extends through a gate region along a longitudinal axis of the gate region. FIGS. 6B, 7B, 8B, 9B, 10B, 11B, 11C, 12A, 12B, 13B, 13D, 14B, 15B, 16B, 17B, 18B, 19, 20, 21, 22, 23A and 24A through 24C illustrate reference cross-section B-B′ illustrated in FIG. 1 that extends through a fin along a longitudinal axis of the fin. FIGS. 7A, 8A, 9A, 10A, 11A, 13A, 13C and 14C illustrate reference cross-section C-C′ illustrated in FIG. 1 that extends through source/drain regions along the longitudinal direction of the gate region. FIGS. 23B through 23D illustrate zoomed-in cross-sectional view of the structure shown in FIG. 23A, in accordance with some embodiments.

In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Further in FIG. 2, a multi-layer stack 201 is formed over the substrate 100. The multi-layer stack 201 includes alternating layers of first semiconductor layers 202A-C (collectively referred to as first semiconductor layers 202) and second semiconductor layers 204A-C (collectively referred to as second semiconductor layers 204). For purposes of illustration and as discussed in greater detail below, the first semiconductor layers 202 will be removed and the second semiconductor layers 204 will be patterned to form channel regions of GAA-FETs.

The multi-layer stack 201 is illustrated as including three layers of each of the first semiconductor layers 202 and the second semiconductor layers 204 for illustrative purposes. In some embodiments, the multi-layer stack 201 may include any number of the first semiconductor layers 202 and the second semiconductor layers 204. Each of the layers of the multi-layer stack 201 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 204 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 202 of the first semiconductor material may be removed without significantly removing the second semiconductor layers 204 of the second semiconductor material, thereby allowing the second semiconductor layers 204 to serve as channel regions of GAA-FETs.

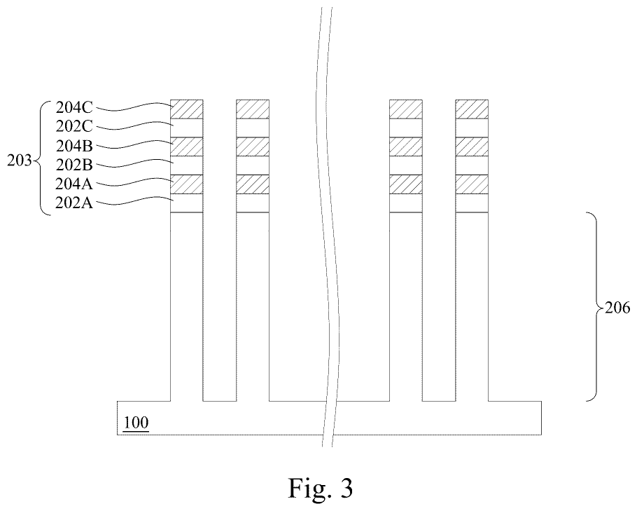

Referring now to FIG. 3, fin structures 206 are formed in the substrate 100 and nanostructures 203 are formed in the multi-layer stack 201, in accordance with some embodiments. In some embodiments, the nanostructures 203 and the fin structures 206 may be formed in the multi-layer stack 201 and the substrate 100, respectively, by etching trenches in the multi-layer stack 201 and the substrate 100. Each fin structure 206 and overlying nanostructures 203 can be collectively referred to as a semiconductor fin extending from the substrate 100. The etching may be any acceptable etch process, such as a reactive ion etch (RIE), neutral beam etch (NBE), the like, or a combination thereof. The etching may be anisotropic. Forming the nanostructures 203 by etching the multi-layer stack 201 may further define first nanostructures 202A-C (collectively referred to as the first nanostructures 202) from the first semiconductor layers 202 and define second nanostructures 204A-C (collectively referred to as the second nanostructures 204) from the second semiconductor layers 204. The first nanostructures 202 and the second nanostructures 204 may further be collectively referred to as nanostructures 203.

The fin structures 206 and the nanostructures 203 may be patterned by any suitable method. For example, the fin structures 206 and the nanostructures 203 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 206. While each of the fin structures 206 and the nanostructures 203 are illustrated as having a consistent width throughout, in other embodiments, the fin structures 206 and/or the nanostructures 203 may have tapered sidewalls such that a width of each of the fin structures 206 and/or the nanostructures 203 continuously increases in a direction towards the substrate 100. In such embodiments, each of the nanostructures 203 may have a different width and be trapezoidal in shape.

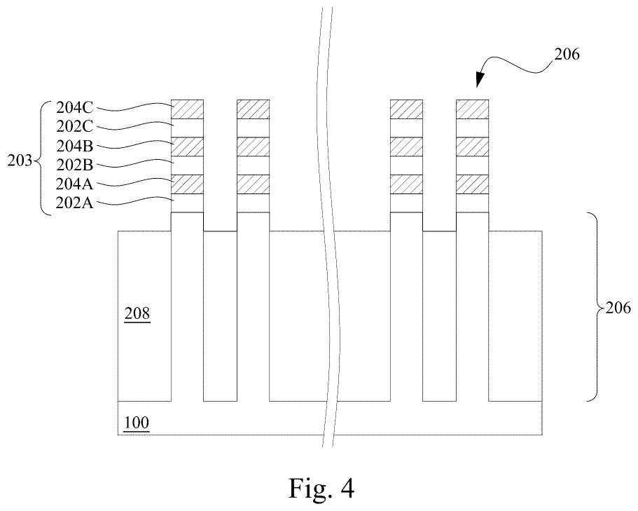

In FIG. 4, shallow trench isolation (STI) regions 208 are formed adjacent the fin structures 206. The STI regions 208 may be formed by depositing an insulation material over the substrate 100, the fin structures 206, and nanostructures 203, and between adjacent fin structures 206. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 203. Although the insulation material is illustrated as a single layer, some embodiments may utilize multiple layers. For example, in some embodiments a liner (not separately illustrated) may first be formed along a surface of the substrate 100, the fin structures 206, and the nanostructures 203. Thereafter, a fill material, such as those discussed above may be formed over the liner.

A removal process is then applied to the insulation material to remove excess insulation material over the nanostructures 203. In some embodiments, a planarization process such as a chemical mechanical polish (CMP), an etch-back process, combinations thereof, or the like may be utilized. The planarization process exposes the nanostructures 203 such that top surfaces of the nanostructures 203 and the insulation material are level after the planarization process is complete.

The insulation material is then recessed to form the STI regions 208. The insulation material is recessed such that upper portions of fin structures 206 protrude from between neighboring STI regions 208. Further, the top surfaces of the STI regions 208 may have a flat surface as illustrated, a convex surface, a concave surface (such as dishing), or a combination thereof. The top surfaces of the STI regions 208 may be formed flat, convex, and/or concave by an appropriate etch. The STI regions 208 may be recessed using an acceptable etching process, such as one that is selective to the material of the insulation material (e.g., etches the material of the insulation material at a faster rate than the material of the fin structures 206 and the nanostructures 203). For example, an oxide removal using, for example, dilute hydrofluoric (dHF) acid may be used.

The process described above with respect to FIGS. 2 through 4 is just one example of how the fin structures 206 and the nanostructures 203 may be formed. In some embodiments, the fin structures 206 and/or the nanostructures 203 may be formed using a mask and an epitaxial growth process. For example, a dielectric layer can be formed over a top surface of the substrate 100, and trenches can be etched through the dielectric layer to expose the underlying substrate 100. Epitaxial structures can be epitaxially grown in the trenches, and the dielectric layer can be recessed such that the epitaxial structures protrude from the dielectric layer to form the fin structures 206 and/or the nanostructures 203. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further in FIG. 4, appropriate wells (not separately illustrated) may be formed in the fin structures 206 and/or the nanostructures 203. In some embodiments with different well types in different device regions (e.g., NFET region and PFET region), different implant steps may be achieved using a photoresist or other masks (not separately illustrated). For example, a photoresist may be formed over the fin structures 206 and the STI regions 208 in the NFET region and the PFET region. The photoresist is patterned to expose the PFET region. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the PFET region, and the photoresist may act as a mask to substantially prevent the first impurities from being implanted into the NFET region. After the implant, the photoresist is removed, such as by an acceptable ashing process.

Following or prior to the implanting of the PFET region, a photoresist or other masks (not separately illustrated) is formed over the fin structures 206, the nanostructures 203, and the STI regions 208 in the NFET region and the PFET region. The photoresist is then patterned to expose the NFET region. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the NFET region, and the photoresist may act as a mask to substantially prevent p-type impurities from being implanted into the PFET region. After the implant, the photoresist may be removed, such as by an acceptable ashing process.

After one or more well implants of the NFET region and PFET region, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

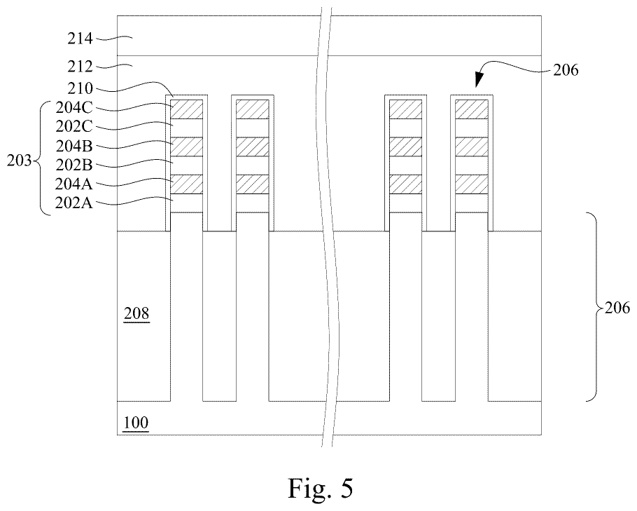

In FIG. 5, a dummy dielectric layer 210 is formed on the fin structures 206 and/or the nanostructures 203. The dummy dielectric layer 210 may be, for example, silicon oxide, silicon nitride, a combination thereof, or the like, and may be deposited or thermally grown according to acceptable techniques. A dummy gate layer 212 is formed over the dummy dielectric layer 210, and a mask layer 214 is formed over the dummy gate layer 212. The dummy gate layer 212 may be deposited over the dummy dielectric layer 210 and then planarized, such as by a CMP. The mask layer 214 may be deposited over the dummy gate layer 212. The dummy gate layer 212 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 212 may be deposited by physical vapor deposition (PVD), CVD, sputter deposition, or other techniques for depositing the selected material. The dummy gate layer 212 may be made of other materials that have a high etching selectivity from the etching of isolation regions. The mask layer 214 may include, for example, silicon nitride, silicon oxynitride, or the like. It is noted that the dummy dielectric layer 210 is shown covering only the fin structures 206 and the nanostructures 203 for illustrative purposes only. In some embodiments, the dummy dielectric layer 210 may be deposited such that the dummy dielectric layer 210 covers the STI regions 208, such that the dummy dielectric layer 210 extends between the dummy gate layer 212 and the STI regions 208.

In FIGS. 6A and 6B, the mask layer 214 (see FIG. 5) may be patterned using acceptable photolithography and etching techniques to form masks 218. The pattern of the masks 218 then may be transferred to the dummy gate layer 212 and to the dummy dielectric layer 210 to form dummy gates 216 and dummy gate dielectrics 211, respectively. The dummy gates 216 cover respective channel regions of the fin structures 206. The pattern of the masks 218 may be used to physically separate each of the dummy gates 216 from adjacent dummy gates 216. The dummy gates 216 may also have a lengthwise direction substantially perpendicular to the lengthwise direction of respective fin structures 206.

In FIGS. 7A and 7B, a first spacer layer 220 and a second spacer layer 222 are formed over the structures illustrated in FIGS. 6A and 6B, respectively. The first spacer layer 220 and the second spacer layer 222 will be subsequently patterned to act as spacers for forming self-aligned source/drain regions. In FIGS. 7A and 7B, the first spacer layer 220 is formed on top surfaces of the STI regions 208; top surfaces and sidewalls of the fin structures 206, the nanostructures 203, and the masks 218; and sidewalls of the dummy gates 216 and the dummy gate dielectric 211. The second spacer layer 222 is deposited over the first spacer layer 220. The first spacer layer 220 may be formed of silicon oxide, silicon nitride, silicon oxynitride, or the like, using techniques such as thermal oxidation or deposited by CVD, ALD, or the like. The second spacer layer 222 may be formed of a material having a different etch rate than the material of the first spacer layer 220, such as silicon oxide, silicon nitride, silicon oxynitride, or the like, and may be deposited by CVD, ALD, or the like. In some embodiments, each of the first spacer layer 220 and the second spacer layer 222 may be single or composite material and include 1˜3 layers.

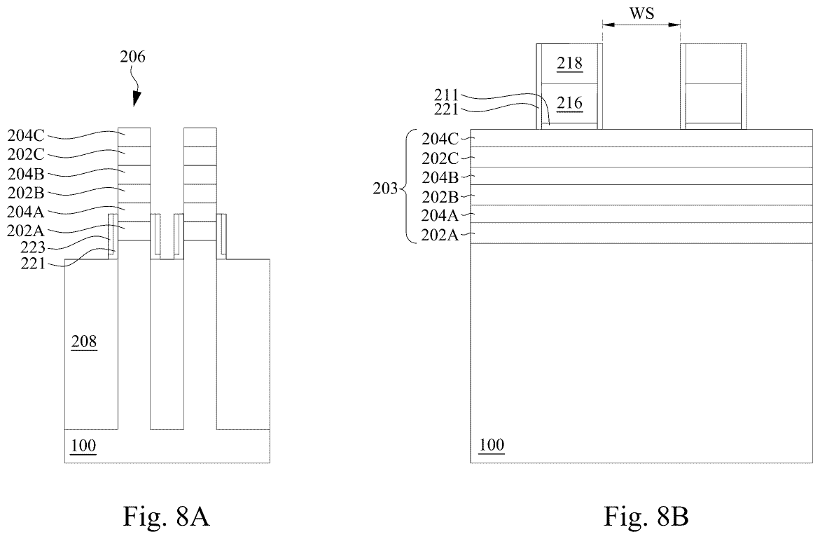

In FIGS. 8A and 8B, the first spacer layer 220 and the second spacer layer 222 are etched to form first spacers 221 and second spacers 223. As will be discussed in greater detail below, the first spacers 221 and the second spacers 223 act to self-align subsequently formed source and drain regions (collectively referred to as source/drain regions), as well as to protect sidewalls of the fin structures 206 and/or nanostructure 203 during subsequent processing. The first spacer layer 220 and the second spacer layer 222 may be etched using a suitable etching process, such as an isotropic etching process (e.g., a wet etching process), an anisotropic etching process (e.g., a dry etching process), or the like. In some embodiments, the material of the second spacer layer 222 has a different etch rate than the material of the first spacer layer 220, such that the first spacer layer 220 may act as an etch stop layer when patterning the second spacer layer 222 and such that the second spacer layer 222 may act as a mask when patterning the first spacer layer 220. For example, the second spacer layer 222 may be etched using an anisotropic etch process wherein the first spacer layer 220 acts as an etch stop layer, wherein remaining portions of the second spacer layer 222 form second spacers 223 as illustrated in FIG. 8A. Thereafter, the second spacers 223 acts as a mask while etching exposed portions of the first spacer layer 220, thereby forming first spacers 221 as illustrated in FIG. 8A.

As illustrated in FIG. 8A, the first spacers 221 and the second spacers 223 are disposed on sidewalls of the fin structures 206 and/or nanostructures 203. In some embodiments, the spacers 221 and 223 only partially remain on sidewalls of the fin structures 206. In some embodiments, no spacer remains on sidewalls of the fin structures 206. As illustrated in FIG. 8B, in some embodiments, the second spacer layer 222 may be removed from over the first spacer layer 220 adjacent the masks 218, the dummy gates 216, and the dummy gate dielectrics 211, and the first spacers 221 are disposed on sidewalls of the masks 218, the dummy gates 216, and the dummy dielectric layers 211. In other embodiments, a portion of the second spacer layer 222 may remain over the first spacer layer 220 adjacent the masks 218, the dummy gates 216, and the dummy gate dielectrics 211.

In some embodiments, the first spacers 221 on gate sidewalls (also called gate spacers) have a small thickness (e.g., in a range from about 1 nm to about 10 nm) so as to reduce gate-to-gate pitch without significant reduction in source/drain region size. In some embodiments, the first spacers 221 on gate sidewalls is formed of as low-dielectric constant (low-k) materials (e.g., porous silicon oxide) having a k-value, for example, less than about 3.5. The low-k material can aid in reducing parasitic capacitance between, for example, the subsequently formed metal gates and source/drain contacts.

As shown in FIG. 8B, a distance WS is between the first spacers 221, and the distance may be regarded as a width for subsequently formed source/drain regions to growth. In some embodiments, the distance WS may be in a range between about 15 nm and about 25 nm.

The above disclosure generally describes a process of forming spacers. Other processes and sequences may be used. For example, fewer or additional spacers may be utilized, different sequence of steps may be utilized (e.g., the first spacers 221 may be patterned prior to depositing the second spacer layer 222), additional spacers may be formed and removed, and/or the like.

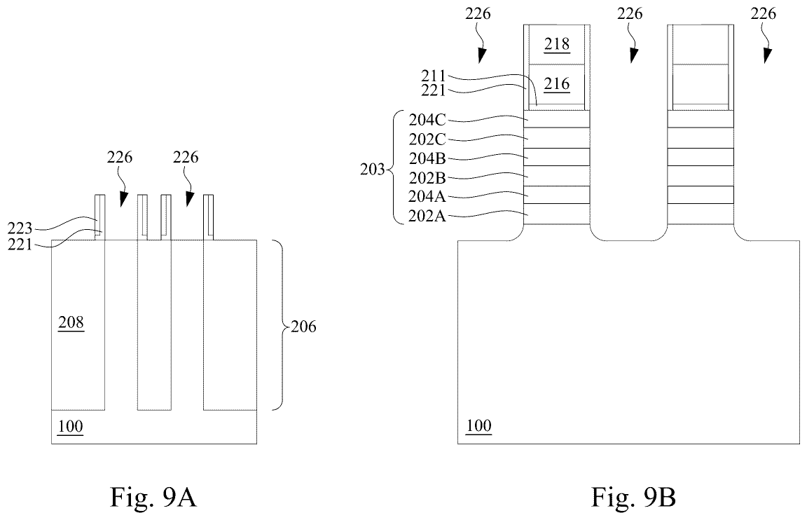

In FIGS. 9A and 9B, source/drain recesses 226 are formed in the fin structures 206, the nanostructures 203, and the substrate 100, in accordance with some embodiments. Epitaxial source/drain regions will be subsequently formed in the source/drain recesses 226. The source/drain recesses 226 may extend through the first nanostructures 202 and the second nanostructures 204, and into the substrate 100. As illustrated in FIG. 9A, bottom surfaces of the source/drain recesses 226 may be level with top surfaces of the STI regions 208, as an example. In some other embodiments, the fin structures 206 may be etched such that bottom surfaces of the source/drain recesses 226 are disposed below the top surfaces of the STI regions 208, or above the top surfaces of the STI regions 208. The source/drain recesses 226 may be formed by etching the fin structures 206, the nanostructures 203, and the substrate 100 using anisotropic etching processes, such as RIE, NBE, or the like. The first spacers 221, the second spacers 223, and the masks 218 mask portions of the fin structures 206, the nanostructures 203, and the substrate 100 during the etching processes used to form the source/drain recesses 226. A single etch process or multiple etch processes may be used to etch each layer of the nanostructures 203 and/or the fin structures 206. Timed etch processes may be used to stop the etching of the source/drain recesses 226 after the source/drain recesses 226 reach a target depth.

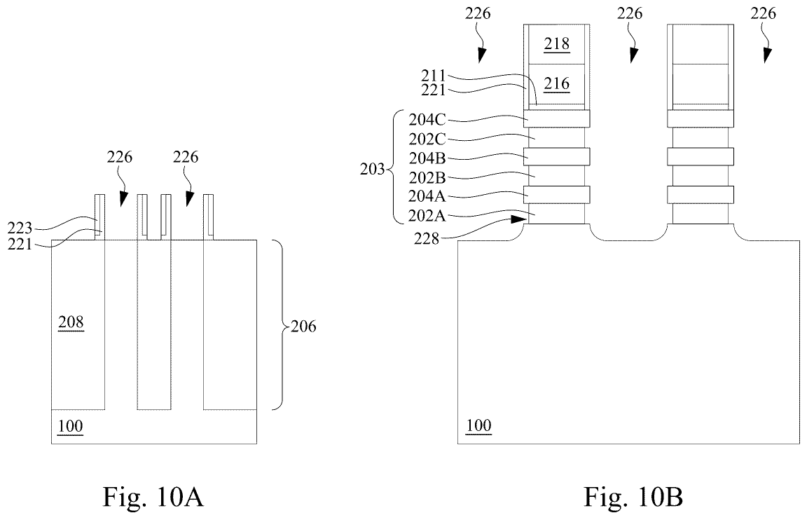

In FIGS. 10A and 10B, portions of sidewalls of the layers of the multi-layer stack 203 formed of the first semiconductor materials (e.g., the first nanostructures 202) exposed by the source/drain recesses 226 are etched to form sidewall recesses 228 between corresponding second nanostructures 204. Although sidewalls of the first nanostructures 202 in recesses 228 are illustrated as being straight in FIG. 10B, the sidewalls may be concave or convex. The sidewalls may be etched using isotropic etching processes, such as wet etching or the like. In some embodiments in which the first nanostructures 202 include, e.g., SiGe, and the second nanostructures 204 include, e.g., Si or SiC, a dry etch process with tetramethylammonium hydroxide (TMAH), ammonium hydroxide (NH₄OH), or the like may be used to etch sidewalls of the first nanostructures 202.

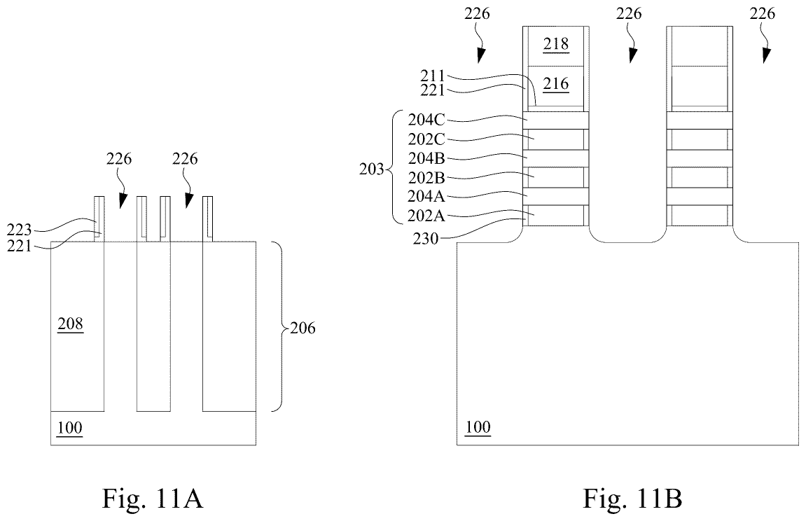

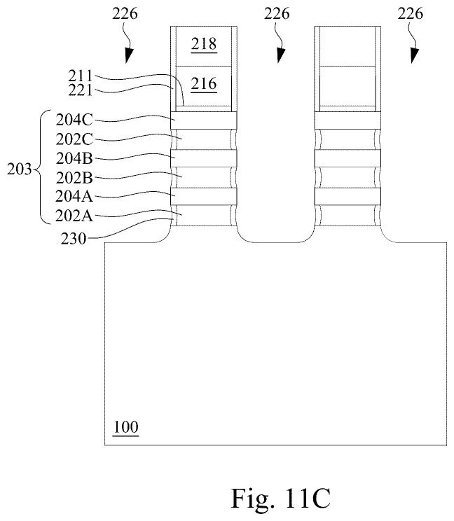

In FIGS. 11A-11C, inner spacers 230 are formed in the sidewall recess 228. The inner spacers 230 may be formed by depositing an inner spacer layer (not separately illustrated) over the structures illustrated in FIGS. 10A and 10B. The inner spacers 230 act as isolation features between subsequently formed source/drain regions and gate structure. As will be discussed in greater detail below, source/drain regions will be formed in the recesses 226, and the first nanostructures 202 will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 230. Although outer sidewalls of the inner spacers 230 are illustrated as being flush with sidewalls of the second nanostructures 204, the outer sidewalls of the inner spacers 230 may extend beyond or be recessed from sidewalls of the second nanostructures 204. In some embodiments, the inner spacers 230 may be single or composite material and include 1˜3 layers.

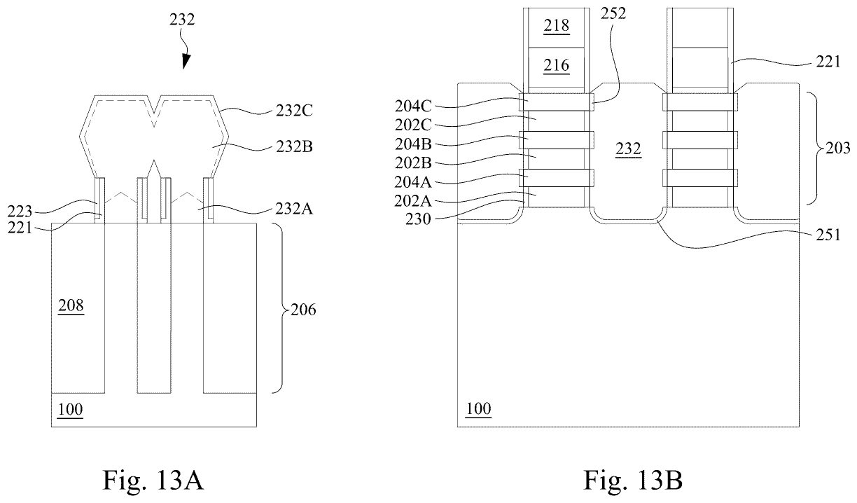

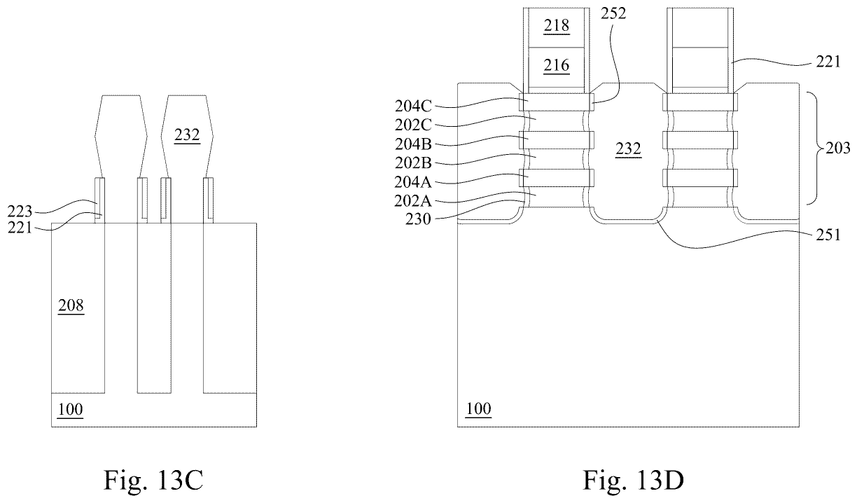

Moreover, although the outer sidewalls of the inner spacers 230 are illustrated as being straight in FIG. 11B, the outer sidewalls of the inner spacers 230 may be concave or convex. As an example, FIG. 11C illustrates an embodiment in which sidewalls of the first nanostructures 202 are concave, outer sidewalls of the inner spacers 230 are concave, and the inner spacers are recessed from sidewalls of the second nanostructures 204. The inner spacer layer may be etched by an anisotropic etching process, such as RIE, NBE, or the like. The inner spacers 230 may be used to prevent damage to subsequently formed source/drain regions (such as the epitaxial source/drain regions 232, discussed below with respect to FIGS. 13A-13D) by subsequent etching processes, such as etching processes used to form gate structures.

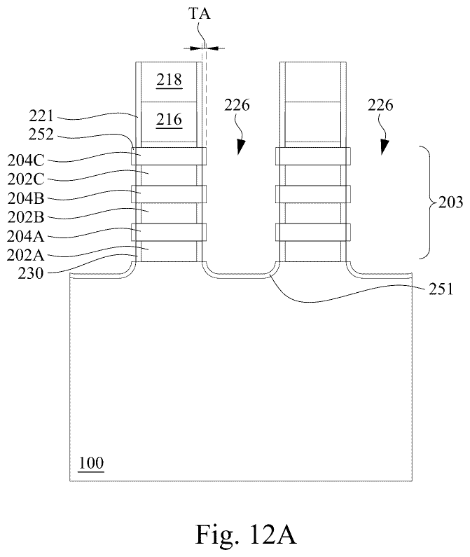

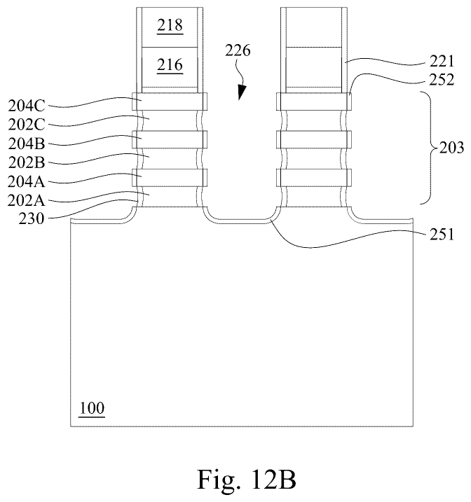

Reference is made to FIGS. 12A and 12B to illustrate formation of a plurality of anti-doping epitaxial layers 251 and 252 on structures as shown in FIGS. 12A and 12B, respectively. In FIGS. 12A and 12B, a plurality of anti-doping epitaxial layers 251 is formed along the exposed bottom surfaces of the source/drain recess 226, and a plurality of anti-doping epitaxial layers 252 is formed along exposed sidewalls of the second nanostructures 204, by using an in-situ or an ex-situ epitaxial process. In FIG. 12A, the anti-doping epitaxial layers 252 are laterally offset from the inner spacers 230. In FIG. 12B, the inner spacers 230 are on the concave surfaces of the nanostructures 204, and the anti-doping epitaxial layers 252 are laterally spaced apart from the inner spacers 230.

In one or more embodiments of the present disclosure, a plurality of undoped semiconductor layers is deposited over the exposed bottom surfaces of the source/drain recess 226 and the exposed sidewalls of the second nanostructures 204 by a deposition process such as CVD process, and the undoped semiconductor layers may be implanted with dopants to form the anti-doping epitaxial layers 251 and 252, followed by an anneal. In some embodiments, material of the undoped semiconductor layers used for forming the anti-doping epitaxial layers 251 and 252 may include acceptable material appropriate for GAA-FETs such as silicon or silicon germanium.

In one or more embodiments, the anti-doping epitaxial layers 251 and 252 may be thin with respect to widths of the nanostructures 204 and the subsequently formed source/drain regions such that the anti-doping epitaxial layers 251 and 252 may not cut off current path between the nanostructures 204 and the subsequently formed source/drain regions. In some embodiments, thickness TA of each of the anti-doping epitaxial layers 251 and 252 may be in a range between about few angstroms to about 5 nm. In some embodiments, the thickness TA of each of the anti-doping epitaxial layers 251 and 252 may be in a range between about few angstroms and about 30 Å. In some embodiments, the thickness TA of each of the anti-doping epitaxial layers 251 and 252 may be less than a thickness of each of the inner spacers 230.

The anti-doping epitaxial layers 251 and 252 may be used to prevent unintended dopant diffusion from the subsequently formed source/drain regions (such as the epitaxial source/drain regions 232, discussed below with respect to FIGS. 13A-13D) to the second nanostructures 204. Therefore, the anti-doping epitaxial layers 251 and 252 have different conductivity type from the subsequently formed source/drain regions. In some embodiments, the anti-doping epitaxial layers 251 and 252 are crystalline materials formed by epitaxial growth, so that the epitaxial source/drain regions 232 can be epitaxially grown from the anti-doping epitaxial layers 251 and 252. In some embodiments, the anti-doping epitaxial layers 251 and 252 may be in-situ or ex-situ doped during growth. The anti-doping epitaxial layers 251 and 252 may have an impurity concentration of between about 5×10¹⁹ atoms/cm³ and about 1×10²¹ atoms/cm³.

In some embodiments, once the subsequently formed source/drain regions formed over the anti-doping epitaxial layers 251 and 252 are p-type epitaxial material, the anti-doping epitaxial layers 251 and 252 are selected to have n-type dopant such as P or As, so that the anti-doping epitaxial layers 251 and 252 may include is SiP or SiAs, for example. In some embodiments, the subsequently formed source/drain regions formed over the anti-doping epitaxial layers 251 and 252 are n-type epitaxial material, the anti-doping epitaxial layers 251 and 252 are selected to have p-type dopant such as B, so that the anti-doping epitaxial layers 251 and 252 may include SiB or Si₁Ge₁₋ₓB, wherein x is in a range between about 0% and about 100%. In some embodiments, the anti-doping epitaxial layers 251 and 252 may include Si₁Ge₁₋ₓB as p-type epitaxial layers, wherein x is in a range between about 0% and about 20%.

In FIGS. 13A-13D, epitaxial source/drain regions 232 are formed in the source/drain recesses 226 and over the anti-doping epitaxial layers 251 and 252. The epitaxial source/drain regions 232 may have a plurality of protruding portions contact with sidewalls of the inner spacers 230 and laterally extending between the anti-doping epitaxial layers 251. The epitaxial source/drain regions 232 may have different conductivity type from anti-doping epitaxial layers 251 and 252, so that the anti-doping epitaxial layers 251 and 252 may suppress the diffusion of the dopant from the epitaxial source/drain regions 232 to the second nanostructures 204 and the substrate 100, and off-state leakage may be reduced.

In some embodiments, the source/drain regions 232 may exert stress on the second nanostructures 204, thereby improving device performance. As illustrated in FIG. 13B, the epitaxial source/drain regions 232 are formed in the source/drain recesses 226 such that each dummy gate 216 is disposed between respective neighboring pairs of the epitaxial source/drain regions 232. In some embodiments, the first spacers 221 are used to separate the epitaxial source/drain regions 232 from the dummy gates 212, and the inner spacers 230 are used to separate the epitaxial source/drain regions 232 from the first nanostructures 202 by an appropriate lateral distance so that the epitaxial source/drain regions 232 do not short out with subsequently formed gates of the resulting GAA-FETs.

In some embodiments, the epitaxial source/drain regions 232 may include any acceptable material appropriate for n-type GAA-FETs. For example, if the second nanostructures 204 are silicon, the epitaxial source/drain regions 232 may include materials exerting a tensile strain on the second nanostructures 204 across the p-type anti-doping epitaxial layers 252, such as silicon carbide, phosphorous doped silicon carbide, silicon phosphide, or the like. In some embodiments, the epitaxial source/drain regions 232 may include any acceptable material appropriate for p-type GAA-FETs. For example, if the second nanostructures 204 are silicon, the epitaxial source/drain regions 232 may comprise materials exerting a compressive strain on the second nanostructures 204 across the n-type anti-doping epitaxial layers 252, such as silicon germanium, boron doped silicon germanium, germanium, germanium tin, or the like. The epitaxial source/drain regions 232 may have surfaces raised from respective upper surfaces of the nanostructures 203 and may have facets.

The epitaxial source/drain regions 232 may be implanted with dopants to form source/drain regions, followed by an anneal. The source/drain regions 232 may have an impurity concentration of between about 1×1020 atoms/cm³ and about 2×10²¹ atoms/cm³. The n-type and/or p-type impurities for source/drain regions may be any of the impurities previously discussed. In some embodiments, the epitaxial source/drain regions 232 may be in situ doped during growth.

In some embodiments, the impurity concentration of the source/drain regions 232 may greater than the impurity concentration of the anti-doping epitaxial layers 251 and 252. The anti-doping epitaxial layers 251 and 252 may be regarded as thin films being lightly-doped with respect to the source/drain regions 232.

As a result of the epitaxy processes used to form the epitaxial source/drain regions 232, upper surfaces of the epitaxial source/drain regions 232 have facets which expand laterally outward beyond sidewalls of the nanostructures 203. In some embodiments, these facets cause adjacent epitaxial source/drain regions 232 to merge as illustrated by FIG. 13A. In some other embodiments, adjacent epitaxial source/drain regions 232 remain separated after the epitaxy process is completed as illustrated by FIG. 13C. In the embodiments illustrated in FIGS. 13A and 13C, the first spacers 221, 223 may be formed to a top surface of the STI regions 208 thereby blocking the lateral epitaxial growth. In some other embodiments, the spacer etch used to form the first spacers 221, 223 may be adjusted to remove the spacer material to allow the epitaxially grown region to extend to the surface of the STI region 208.

In some embodiments, the epitaxial source/drain regions 232 may include one or more semiconductor material layers. For example, the epitaxial source/drain regions 232 may include any number of distinguished semiconductor material layer formed of different semiconductor materials and may be doped to different dopant concentrations.

FIG. 13D illustrates an embodiment in which sidewalls of the first nanostructures 202 are concave, outer sidewalls of the inner spacers 230 are concave, and the inner spacers 230 are recessed from sidewalls of the second nanostructures 204. As illustrated in FIG. 13D, the epitaxial source/drain regions 232 may be formed in contact with the inner spacers 230 and may extend past sidewalls of the second nanostructures 204 and the anti-doping epitaxial layers 252.

It is noted that the anti-doping epitaxial layers 251, 252 and the epitaxial source/drain regions 232 may be formed through epitaxially growth process. In one or more embodiments of the present disclosure, formation of the anti-doping epitaxial layers 251, 252 and the epitaxial source/drain regions 232 can be in-situ achieved, i.e., realized in the same processing chamber. In some other embodiments, the anti-doping epitaxial layers 251, 252 are can be ex-situ formed.

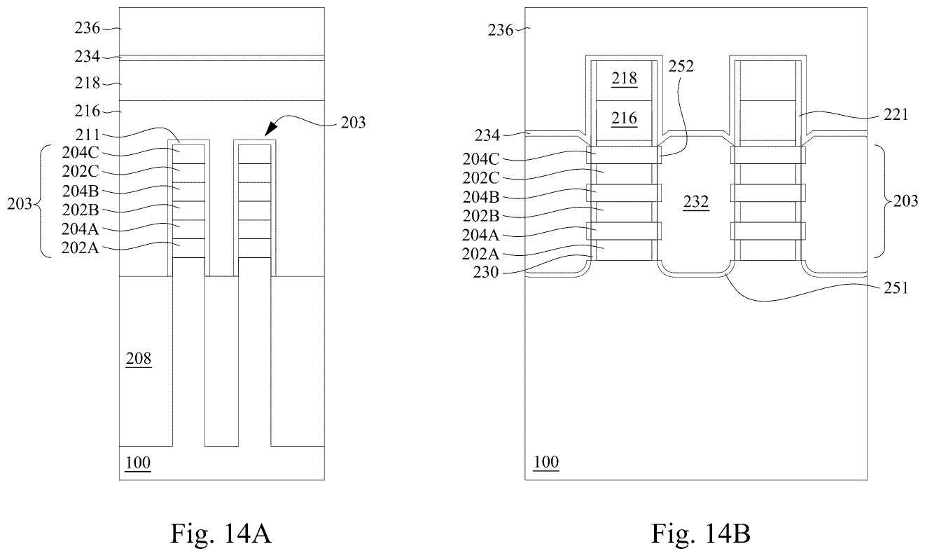

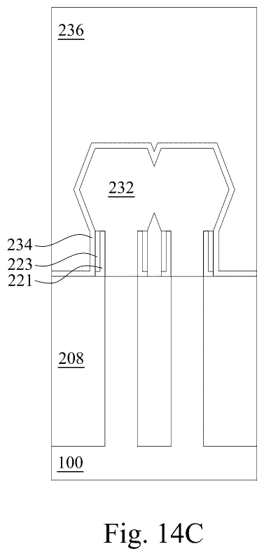

In FIGS. 14A-14C, an interlayer dielectric (ILD) layer 236 is deposited over the structure illustrated in FIGS. 13A-13D. The ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 234 is disposed between the ILD layer 236 and the epitaxial source/drain regions 232, the masks 214, and the first spacers 221. The CESL 234 may comprise a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 236.

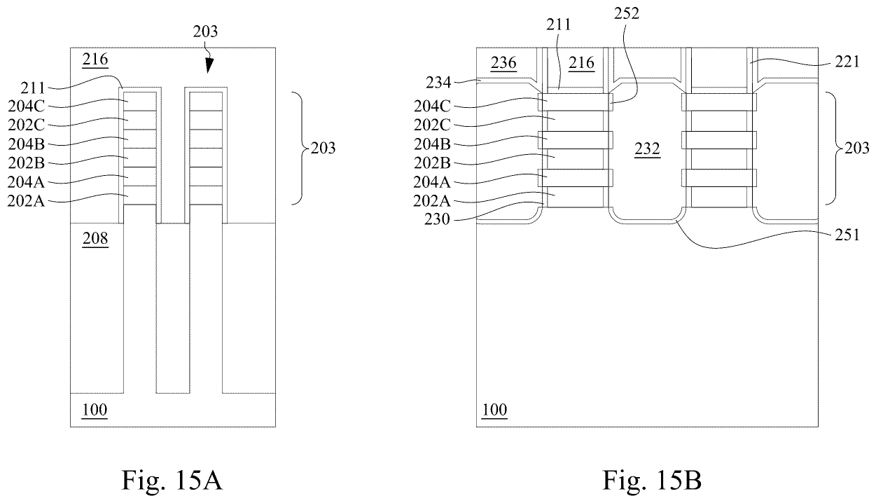

In FIGS. 15A-15B, a planarization process, such as a CMP, may be performed to level the top surface of the ILD layer 236 with the top surfaces of the dummy gates 216 or the masks 218. The planarization process may also remove the masks 218 on the dummy gates 216, and portions of the first spacers 221 along sidewalls of the masks 218. After the planarization process, top surfaces of the dummy gates 216, the first spacers 221, and the ILD layer 236 are level within process variations. Accordingly, the top surfaces of the dummy gates 212 are exposed through the ILD layer 236. In some embodiments, the masks 218 may remain, in which case the planarization process levels the top surface of the ILD layer 236 with top surface of the masks 218 and the first spacers 221.

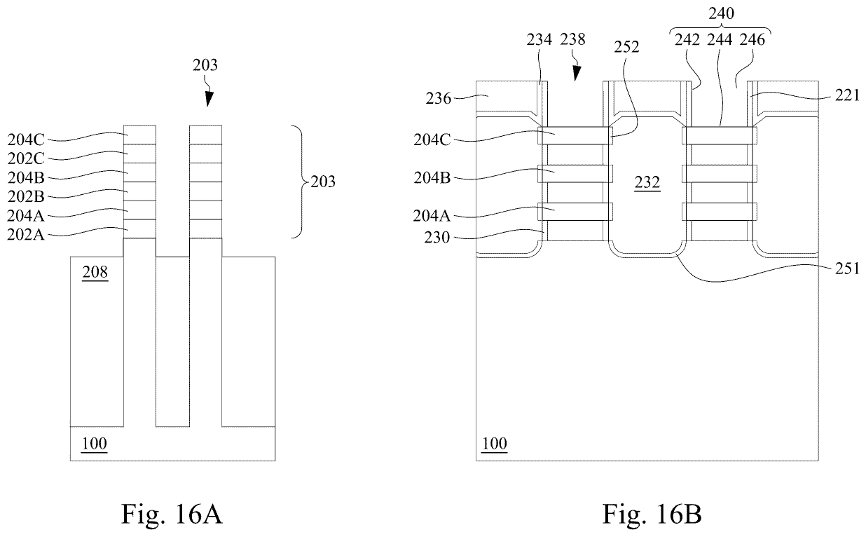

In FIGS. 16A and 16B, the dummy gates 216, and the masks 218 if present, are removed in one or more etching steps, so that gate trenches 238 are formed between corresponding gate spacers 221. In some embodiments, portions of the dummy gate dielectrics 211 in the gate trenches 238 are also be removed. In some embodiments, the dummy gates 216 and the dummy gate dielectrics 211 are removed by an anisotropic dry etch process. For example, the etching process may include a dry etch process using reaction gas(es) that selectively etch the dummy gates 216 at a faster rate than the protective layer 237 or the first spacers 221. Each gate trench 238 exposes and/or overlies portions of nanostructures 204, which will serve as channel regions in subsequently completed GAA-FETs. The nanostructures 204 serving as the channel regions are disposed between neighboring pairs of the epitaxial source/drain regions 232. During the removal, the dummy dielectric layers 211 may be used as etch stop layers when the dummy gates 216 are etched. The dummy dielectric layers 211 may then be removed after the removal of the dummy gates 216.

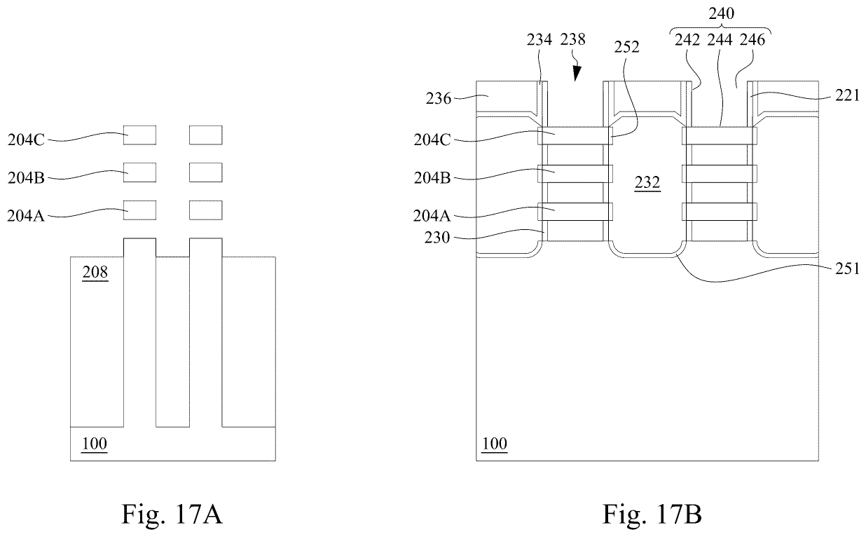

In FIGS. 17A and 17B, the first nanostructures 202 in the gate trenches are removed by an isotropic etching process such as wet etching or the like using etchants which are selective to the materials of the first nanostructures 202. Stated differently, the first nanostructures 202 are removed by using a selective etching process that etches the first nanostructures 202 at a faster etch rate than it etches the second nanostructures 204, thus forming spaces between the second nanostructures 204 (also referred to as sheet-to-sheet spaces if the nanostructures 204 are nanosheets). This step can be referred to as a channel release process. At this interim processing step, the spaces between second nanostructures 204 may be filled with ambient environment conditions (e.g., air, nitrogen, etc). In some embodiments, the second nanostructures 204 can be referred to as nanosheets, nanowires, nanoslabs, nanorings having nano-scale size (e.g., a few nanometers), depending on their geometry. For example, in some embodiments the second nanostructures 204 may be trimmed to have a substantial rounded shape (i.e., cylindrical) due to the selective etching process for completely removing the first nanostructures 202. In that case, the resultant second nanostructures 204 can be called nanowires.

In embodiments in which the first nanostructures 202 include, e.g., SiGe, and the second nanostructures 204 include, e.g., Si or SiC, tetramethylammonium hydroxide (TMAH), ammonium hydroxide (NH₄OH) or the like may be used to remove the first nanostructures 202. In some embodiments, both the channel release step and the previous step of laterally recessing first nanostructures 202 (i.e., the step as illustrated in FIGS. 10A-10B) use a selective etching process that etches first nanostructures 202 (e.g., SiGe) at a faster etch rate than etching second nanostructures 204 (e.g., Si), and therefore these two steps may use the same etchant chemistry in some embodiments. In this case, the etching time/duration of channel release step is longer than the etching time/duration of the previous step of laterally recessing first nanostructures 202, so as to completely remove the sacrificial nanostructures 202.

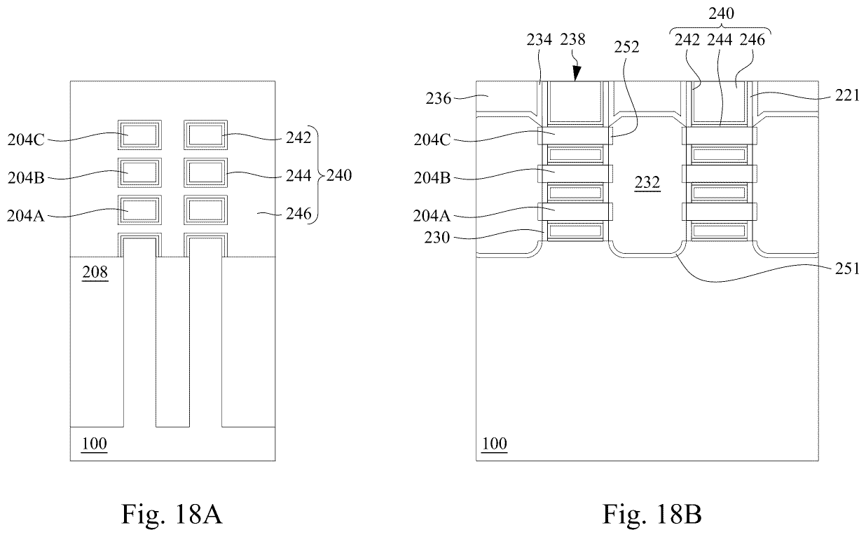

In FIGS. 18A and 18B, replacement gate structures 240 are respectively formed in the gate trenches 238 to surround each of the nanosheets 204 suspended in the gate trenches 238. The gate structures 240 may be final gates of GAA FETs. The final gate structure may be a high-k/metal gate stack, however other compositions are possible. In some embodiments, each of the gate structures 240 forms the gate associated with the multi-channels provided by the plurality of nanosheets 204. For example, high-k/metal gate structures 240 are formed within the sheet-to-sheet spaces provided by the release of nanosheets 204. In various embodiments, the high-k/metal gate structure 240 includes an interfacial layer 242 formed around the nanosheets 204, a high-k gate dielectric layer 244 formed around the interfacial layer 242, and a gate metal layer 246 formed around the high-k gate dielectric layer 244 and filling a remainder of gate trenches 238. Formation of the high-k/metal gate structures 240 may include one or more deposition processes to form various gate materials, followed by a CMP process to remove excessive gate materials, resulting in the high-k/metal gate structures 240 having top surfaces level with a top surface of the protective layer 237. As illustrated in the cross-sectional view of FIG. 18A, the high-k/metal gate structure 240 surrounds each of the nanosheets 204, and thus is referred to as a gate of a GAA FET.

In some embodiments, the interfacial layer 242 is silicon oxide formed on exposed surfaces of semiconductor materials in the gate trenches 238 by using, for example, thermal oxidation, chemical oxidation, wet oxidation or the like. As a result, surface portions of the nanosheets 204 exposed in the gate trenches 238 are oxidized into silicon oxide to form interfacial layer 242.

In some embodiments, the high-k gate dielectric layer 244 includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

In some embodiments, the gate metal layer 246 includes one or more metal layers. For example, the gate metal layer 246 may include one or more work function metal layers stacked one over another and a fill metal filling up a remainder of gate trenches 238. The one or more work function metal layers in the gate metal layer 246 provide a suitable work function for the high-k/metal gate structures 240. For an n-type GAA FET, the gate metal layer 246 may include one or more n-type work function metal (N-metal) layers. The n-type work function metal may exemplarily include, but are not limited to, titanium aluminide (TiAl), titanium aluminium nitride (TiAIN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. On the other hand, for a p-type GAA FET, the gate metal layer 246 may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. In some embodiments, the fill metal in the gate metal layer 246 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAIN, or other suitable materials.

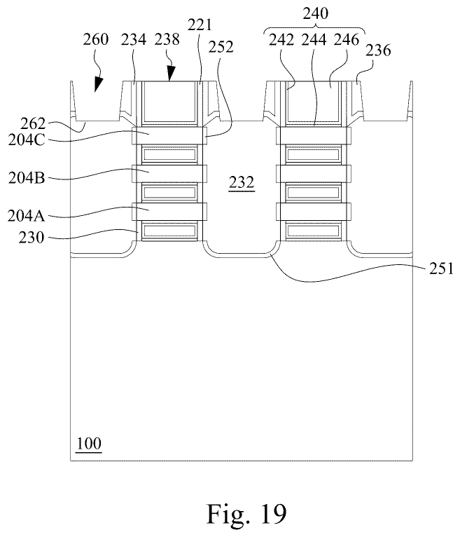

Reference is made to FIGS. 19 through 21 to illustrate formation of the source/drain contacts 264. In FIG. 19, one or more etching processes are performed to form contact openings 260 extending though the ILD layer 236 and the CESL 234 to expose the source/drain epitaxy structures 232. As illustrated in FIG. 19, in some embodiments, portions of the source/drain epitaxy structures 232 are etched so that the contact openings 260 extend into the source/drain epitaxy structures 232.

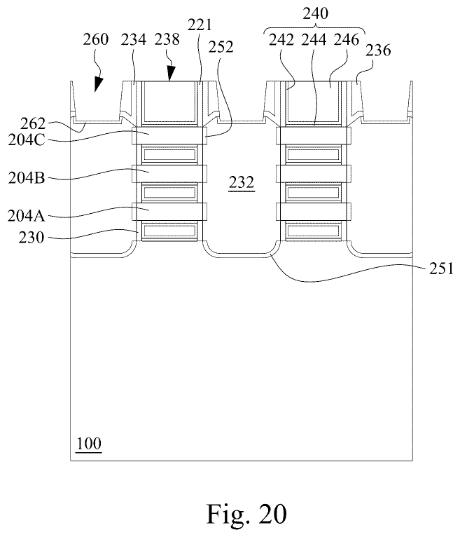

In FIG. 20, silicide regions 262 are formed over the source/drain epitaxy regions 232. The silicide regions 262 may be formed by first depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the epitaxial source/drain regions 232, then performing a thermal anneal process to form the silicide regions 262. The un-reacted portions of the deposited metal are then removed, e.g., by an etching process. Although the silicide regions 262 are referred to as silicide regions, regions 262 may also be germanide regions, or silicon germanide regions (e.g., regions comprising silicide and germanide). In certain embodiments, the silicide regions 262 is formed of titanium silicide (TiSi).

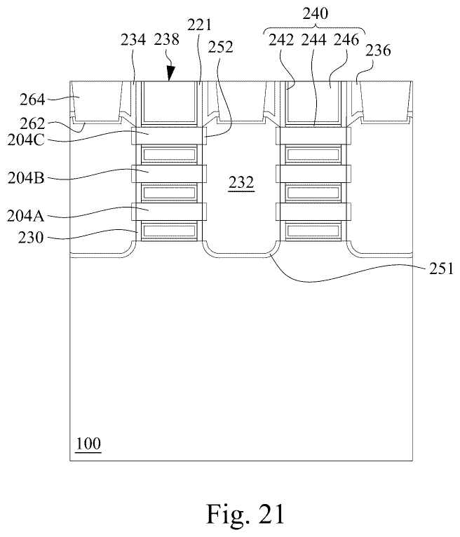

In FIG. 21, once the silicide regions 262 have been formed, a conductive material may be formed on the silicide regions 262, filling and overfilling the contact openings 260. The conductive material may comprise tungsten, although other suitable materials such as aluminum, copper, tungsten nitride, rhuthenium, silver, gold, rhodium, molybdenum, nickel, cobalt, cadmium, zinc, alloys of these, combinations thereof, and the like, may alternatively be utilized. Any suitable deposition method, such as PVD, CVD, ALD, plating (e.g., electroplating), and reflow, may be used to form the conductive material.

Once the contact openings have been filled, excess portions of the conductive material outside of the contact openings may be removed through a planarization process such as CMP, although any suitable removal process may be used. The source/drain contacts 264 are thus formed in the contact openings and over the silicide regions 262. As illustrated in FIG. 21, the source/drain contact 264 has an inverted trapezoidal cross-section, and a lateral distance from the source/drain contact 264 to the gate spacer 221 increases from top of the source/drain contact 22 to bottom of the source/drain contact. In FIG. 21, each of the source/drain contacts 264 has an inverted trapezoidal cross-section, and a lateral distance from the source/drain contact 264 to the gate spacer 221 increases from top of the source/drain contact 264 to bottom of the source/drain contact 264.

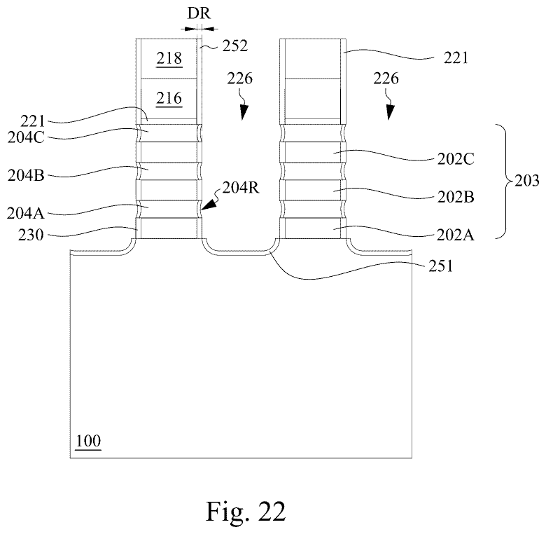

Reference is made to FIG. 22 to illustrate that continued with FIG. 11A, the sidewall of the second nanostructures 204 are etched. Portions of sidewalls of the layers exposed by the source/drain recesses 226 are etched and the sidewalls of the second nanostructures 204 are pushed and concave. A plurality of recesses 204R is formed on the exposed sidewalls of the second nanostructures 204. In some embodiments the recesses 204R may be etched using isotropic etching processes, such as wet etching or the like. The first nanostructures 202 may be protected by the inner spacers 230 during etching the second nanostructures 204.

As illustrated in FIG. 22, the convex surface of one of the second nanostructures 204 has a horizontal distance DR from to the innermost point of the convex surface of one of the second nanostructures 204. The distance DR may be regarded as depths of the lateral recesses 204R on the second nanostructures 204. In some embodiments, the distance DR is in a range between about 0 nm and 5 nm. In some embodiments, the distance DR is less than the thickness of each of the inner spacers 230.

After the second nanostructures 204 are etched and convex, the anti-doping epitaxial layers 252 are formed in the recesses 204R, conformally extend along the convex surfaces of the second nanostructures 204 and have curved profile. In some embodiments, the anti-doping epitaxial layers 252 may be formed to fill the recesses 204R, so that the anti-doping epitaxial layers 252 may have U-shape profiles corresponding to the recesses 204R and have a thickness corresponding the distance DR of the recesses 204R. The horizontal distance DR is controlled so that amount of the anti-doping epitaxial layers 252 may be controlled and may not unintendedly cut off the current path in a formed transistor.

FIG. 23A illustrates that one or more processes are performed to form the epitaxial source/drain regions 232 and source/drain contacts 264 on the structure as illustrated in FIG. 22. A difference between the structure in FIG. 21 and the structure in FIG. 23A is that the epitaxial source/drain regions 232 have protruding portions extends between the inner spacers 230.

FIGS. 23B through 23D illustrate zoom-in views of one of the second nanostructures 204 near the recess 204R in FIG. 23A according to some embodiments, wherein the second nanostructure 204 has a height HC.

FIG. 23B illustrates that a ratio of the distance DR to the height HC is less than 1 according to some embodiments. FIG. 23C illustrates that a ratio of the distance DR to the height HC is equal to 1 according to some embodiments. In some embodiments, the ratio of the distance DR to the height HC is in a range between about 0.1 and about 1. In some embodiments, the ratio of the distance DR to the height HC is in a range between about 0.2 and about 0.5. FIG. 23D illustrates a ratio of the distance DR to the height HC is equal to 1 and the recess 204R has a cone-like profile, so that that the anti-doping epitaxial layer 252 along the recess 204 may also have a cone-like shape.

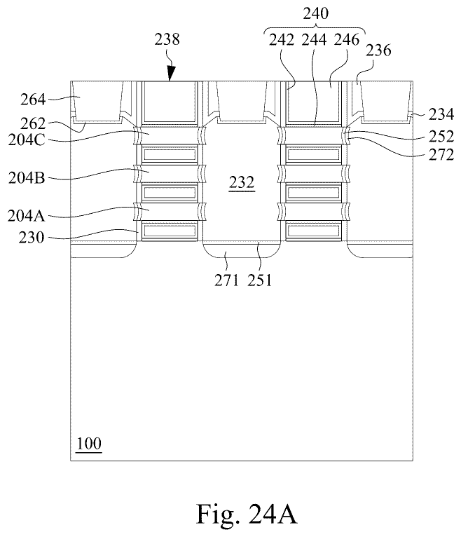

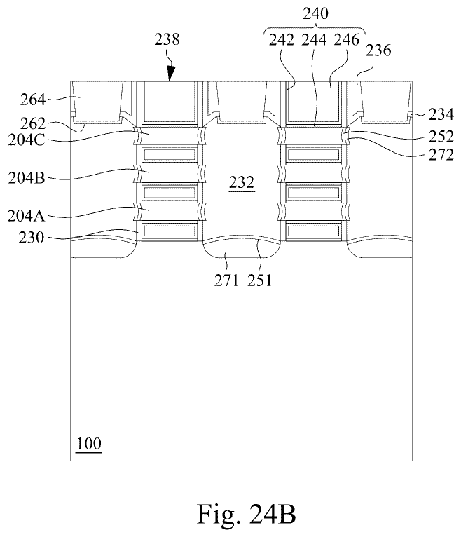

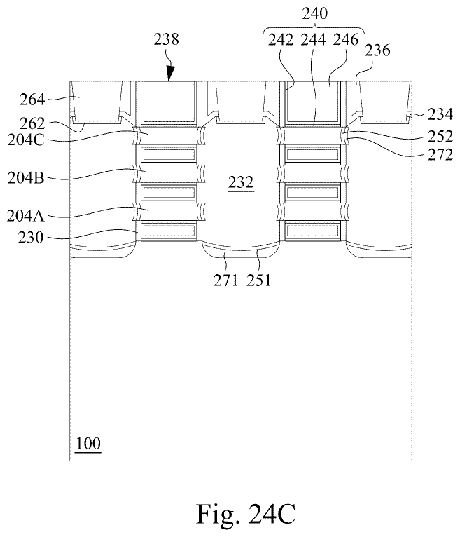

Reference is made to FIGS. 24A through 24C to illustrate forming dopant-free semiconductor layers 271 and 272 before the anti-doping epitaxial layers 251 and 252 are formed. The dopant-free semiconductor layers 271 are formed on the bottoms of the source/drain recesses 226. The dopant-free semiconductor layers 272 are formed in the recess 204R on the sidewalls of the second nanostructures 204. In one or more embodiments, the dopant-free semiconductor layers 271 and 272 may be undoped semiconductor material such as undoped silicon.

The dopant-free semiconductor layer 271 on the bottom of the source/drain recesses 226 may be regarded as a refilled material so that the bottoms of the epitaxial source/drain regions 232 are raised. The anti-doping epitaxial layers 251 may be formed over top surfaces of the dopant-free semiconductor layer 271. FIG. 24A illustrates the anti-doping epitaxial layers 251 and the dopant-free semiconductor layers 271 have flat profile according to some embodiments. FIG. 24B illustrates the anti-doping epitaxial layers 251 and the dopant-free semiconductor layers 271 have concave profile according to some embodiments. FIG. 24C illustrates the anti-doping epitaxial layers 251 and the dopant-free semiconductor layers 271 have convex profile according to some embodiments. Heights of the anti-doping epitaxial layers 251 may be increased to near the bottom ends of the bottommost inner spacers 230.

In some embodiments, the dopant-free semiconductor layer 272 may be formed in the recess 204R on the sidewalls of the second nanostructures 204 so that the amounts of the anti-doping epitaxial layers 252 in the recesses 204R may be controlled. In some embodiments, the dopant-free semiconductor layers 272 formed in the recess 204R on the sidewalls of the second nanostructures 204 may be controlled not to be deposited, or with a negligible thickness sheet through etching precursor flow tuning (e.g. high HCl flow). Therefore, each of the dopant-free semiconductor layers 272 may have a thickness less than a thickness of each of the dopant-free semiconductor layers 272 on the bottoms of the source/drain recesses 226.

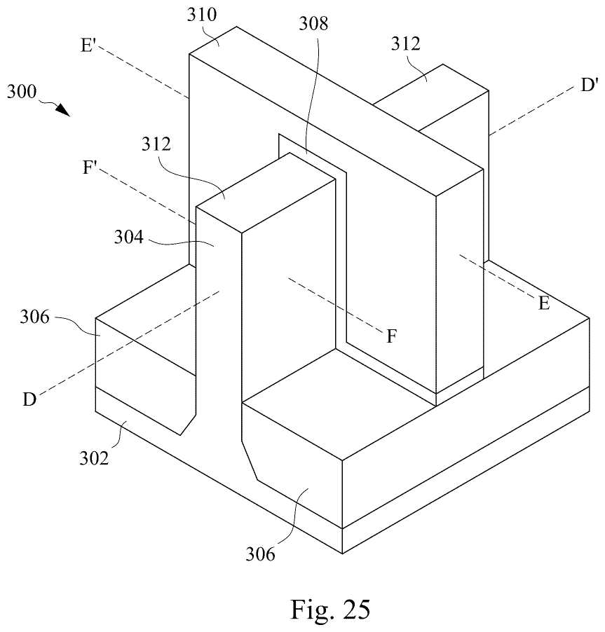

FIG. 25 illustrates an example of a FinFET 300 in a perspective view. The FinFET 300 includes a substrate 302 and a fin 304 protruding above the substrate 302. Isolation regions 306 are formed on opposing sides of the fin 304, with the fin 304 protruding above the isolation regions 306. A gate dielectric 308 is along sidewalls and over a top surface of the fin 304, and a gate electrode 310 is over the gate dielectric 308. Source/drain regions 312 are in the fin 304 and on opposing sides of the gate dielectric 308 and the gate electrode 310. FIG. 25 further illustrates reference cross-sections that are used in later figures. Cross-section E-E′ extends along a longitudinal axis of the gate electrode 310 of the FinFET 300. Cross-section D-D′ is perpendicular to cross-section E-E′ and is along a longitudinal axis of the fin 304 and in a direction of, for example, a current flow between the source/drain regions 312. Cross-section F-F′ is parallel to cross-section E-E′ and is across the source/drain region 312. Subsequent figures refer to these reference cross-sections for clarity.

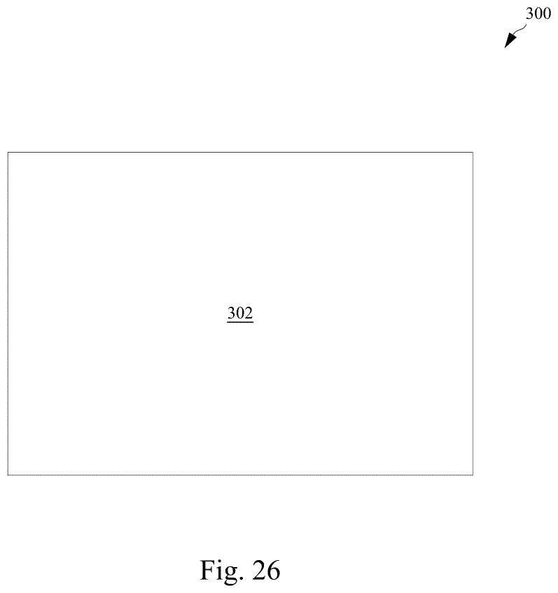

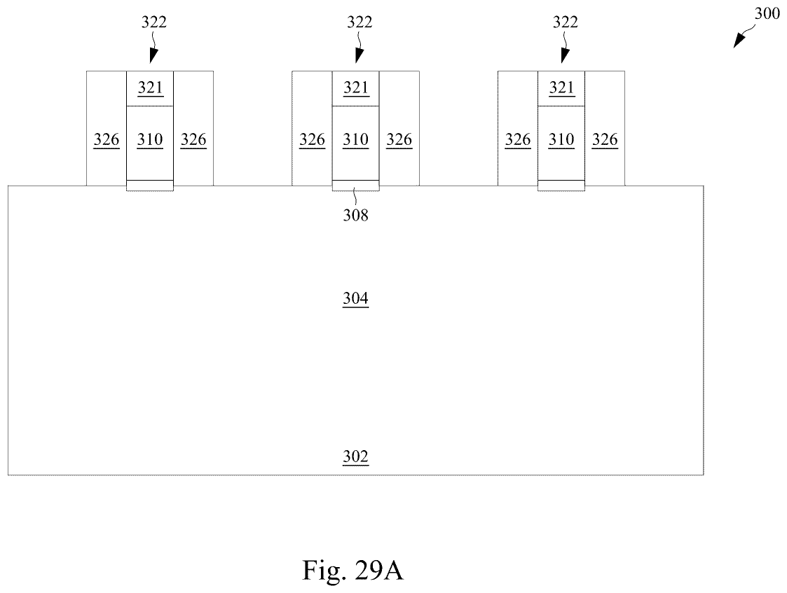

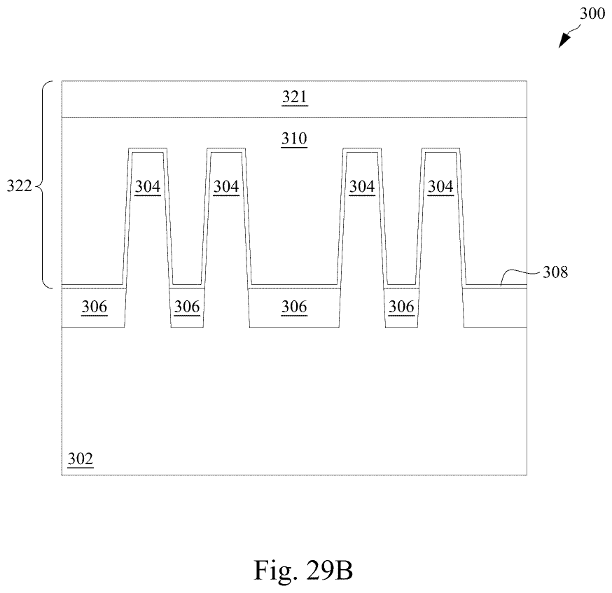

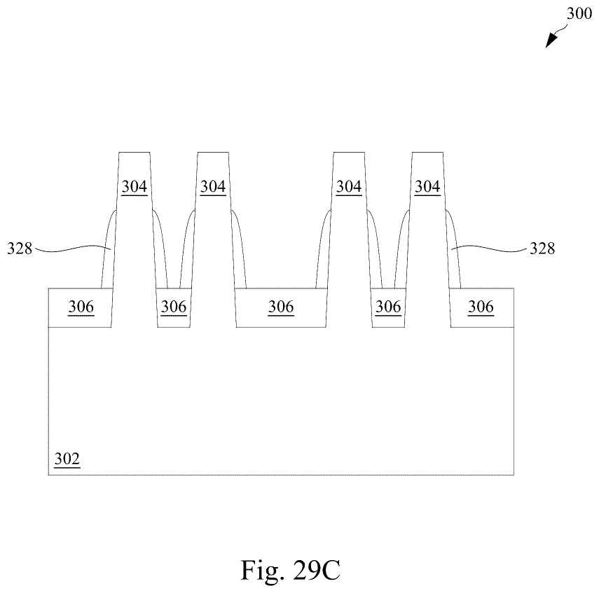

FIGS. 26 through 28, 29B and 33B illustrate cross-sectional views of the FinFET device along cross-section E-E′ of FIG. 25, in accordance with some embodiments. FIGS. 29A, 30A, 31A, 32A, 33A and 34 illustrate cross-sectional views of the FinFET device along cross-section D-D′ of FIG. 25, in accordance with some embodiments. FIGS. 29C, 30B, 31B, 32B, 32C and 33C illustrate cross-sectional views of the FinFET device along cross-section F-F′ of FIG. 25, in accordance with some embodiments.

FIG. 26 illustrates a cross-sectional view of a substrate 302. The substrate 302 may be a semiconductor substrate, such as a bulk semiconductor, a semiconductor-on-insulator (SOI) substrate, or the like, which may be doped (e.g., with a p-type or an n-type dopant) or undoped. The substrate 302 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 302 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GalnP, and/or GaInAsP; or combinations thereof.

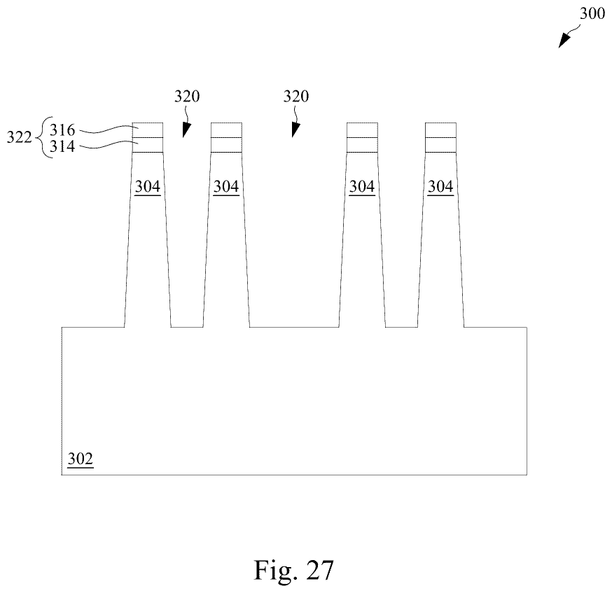

Referring next to FIG. 27, the substrate 302 shown in FIG. 26 is patterned using, for example, photolithography and etching techniques. For example, a mask layer, such as a pad oxide layer 314 and an overlying pad nitride layer 316, is formed over the substrate 302. The pad oxide layer 314 may be a thin film comprising silicon oxide formed, for example, using a thermal oxidation process. The pad oxide layer 314 may act as an adhesion layer between the substrate 302 and the overlying pad nitride layer 316 and may act as an etch stop layer for etching the pad nitride layer 316. In some embodiments, the pad nitride layer 316 is formed of silicon nitride, silicon oxynitride, silicon carbonitride, the like, or a combination thereof, and may be formed using low-pressure chemical vapor deposition (LPCVD) or plasma enhanced chemical vapor deposition (PECVD), as examples.

The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. In this example, the photoresist material is used to pattern the pad oxide layer 314 and pad nitride layer 316 to form a patterned mask 318, as illustrated in FIG. 27.

The patterned mask 318 is subsequently used to pattern exposed portions of the substrate 302 to form trenches 320, thereby defining semiconductor fins 304 (may also be referred to as fins) between adjacent trenches 320 as illustrated in FIG. 27. In some embodiments, the semiconductor fins 304 are formed by etching trenches in the substrate 302 using, for example, reactive ion etch (RIE), neutral beam etch (NBE), the like, or a combination thereof. The etch may be anisotropic. In some embodiments, the trenches 320 may be strips (viewed from in the top) parallel to each other, and closely spaced with respect to each other. In some embodiments, the trenches 320 may be continuous and surround the semiconductor fins 304. After semiconductor fins 304 are formed, the patterned mask 318 may be removed by etching or any suitable method.

The fins 304 may be patterned by any suitable method. For example, the fins 304 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

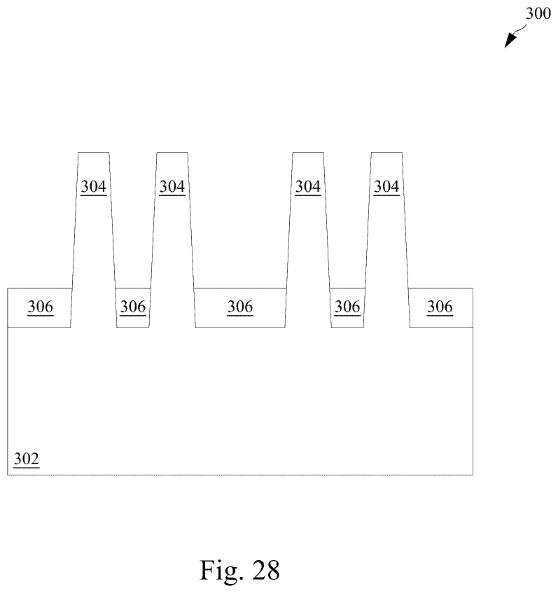

Next, FIG. 28 illustrates the formation of an insulation material between neighboring semiconductor fins 304 to form isolation regions 306. The insulation material may be an oxide (e.g., silicon oxide), a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials and/or other formation processes may be used. In the illustrated embodiment, the insulation material is silicon oxide formed by a FCVD process. An anneal process may be performed after the insulation material is formed. A planarization process, such as a chemical mechanical polish (CMP), may remove any excess insulation material (and, if present, the patterned mask 318) and form top surfaces of the isolation regions 306 and top surfaces of the semiconductor fins 304 that are coplanar (not shown).

In some embodiments, the isolation regions 306 include a liner, e.g., a liner oxide (not shown), at the interface between the isolation region 306 and the substrate 302/semiconductor fins 304. In some embodiments, the liner oxide is formed to reduce crystalline defects at the interface between the substrate 302 and the isolation region 306. Similarly, the liner oxide may also be used to reduce crystalline defects at the interface between the semiconductor fins 304 and the isolation region 306. The liner oxide (e.g., silicon oxide) may be a thermal oxide formed through a thermal oxidation of a surface layer of substrate 302, although other suitable method may also be used to form the liner oxide.

Next, the isolation regions 306 are recessed to form shallow trench isolation (STI) regions. The isolation regions 306 are recessed such that the upper portions of the semiconductor fins 304 protrude from between neighboring isolation regions 306. The top surfaces of the isolation regions 306 may have a flat surface (as illustrated), a convex surface, a concave surface (such as dishing), or a combination thereof. The top surfaces of the isolation regions 306 may be formed flat, convex, and/or concave by an appropriate etch. The isolation regions 306 may be recessed using an acceptable etching process, such as one that is selective to the material of the isolation regions 306. For example, a chemical oxide removal using dilute hydrofluoric (dHF) acid may be used.

FIGS. 25 through 28 illustrate an embodiment of forming fins 304, but fins may be formed in various different processes. In one example, a dielectric layer can be formed over a top surface of a substrate; trenches can be etched through the dielectric layer; homoepitaxial structures can be epitaxially grown in the trenches; and the dielectric layer can be recessed such that the homoepitaxial structures protrude from the dielectric layer to form fins. In another example, heteroepitaxial structures can be used for the fins. For example, the semiconductor fins can be recessed, and a material different from the semiconductor fins may be epitaxially grown in their place.

In an even further example, a dielectric layer can be formed over a top surface of a substrate; trenches can be etched through the dielectric layer; heteroepitaxial structures can be epitaxially grown in the trenches using a material different from the substrate; and the dielectric layer can be recessed such that the heteroepitaxial structures protrude from the dielectric layer to form fins.

In some embodiments where homoepitaxial or heteroepitaxial structures are epitaxially grown, the grown materials may be in situ doped during growth, which may obviate prior and subsequent implantations although in situ and implantation doping may be used together. Still further, it may be advantageous to epitaxially grow a material in an NMOS region different from the material in a PMOS region. In various embodiments, the fins may comprise silicon germanium (SiₓGe₁₋ₓ, where x can be between approximately 0 and 1), silicon carbide, pure or substantially pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AIP, GaP, and the like.

FIGS. 29A-29C illustrates formation of dummy gate structures 322 over the semiconductor fins 304. The dummy gate structures 322 each include gate dielectric 308 and gate 310, in some embodiments. The dummy gate structure 322 may be formed by patterning a mask layer, a gate layer and a gate dielectric layer, where the mask layer, the gate layer and the gate dielectric layer comprise a same material as the mask 321, the gate 310, and the gate dielectric 308, respectively. To form the dummy gate structures 322, the gate dielectric layer is formed on the semiconductor fins 304 and the isolation regions 306. The gate dielectric layer may be, for example, silicon oxide, silicon nitride, multilayers thereof, or the like, and may be deposited or thermally grown according to acceptable techniques. The formation methods of the gate dielectric layer may include molecular-beam deposition (MBD), atomic layer deposition (ALD), plasma-enhanced CVD (PECVD), and the like.

The gate layer is formed over the gate dielectric layer, and the mask layer is formed over the gate layer. The gate layer may be deposited over the gate dielectric layer and then planarized, such as by a CMP. The mask layer may be deposited over the gate layer. The gate layer may be formed of, for example, polysilicon, although other materials may also be used. The mask layer may be formed of, for example, silicon nitride or the like.

After the gate dielectric layer, the gate layer, and the mask layer are formed, the mask layer may be patterned using acceptable photolithography and etching techniques to form mask 321. The pattern of the mask 321 may then be transferred to the gate layer and the gate dielectric layer by a suitable etching technique to form gates 310 and gate dielectrics 308, respectively. Each gate 310 and a corresponding gate dielectric 308 collectively serve as a dummy gate structure 322 that wrap around channel regions of the semiconductor fins 304. The gate 310 may also have a lengthwise direction substantially perpendicular to the lengthwise direction of respective semiconductor fins 304.

Still referring to FIGS. 29A-29C, after forming the dummy gate structures 322, gate spacers 326 are formed on opposing sidewalls of the gate structures 322, and fin spacers 328 are formed on opposing sidewalls of the fins 304. In some embodiments, the spacers 326 and 328 are formed in same processing. For example, a spacer material layer is first deposited as a blanket layer over the substrate, and then the spacer material layer is anisotropically etched, such that horizontal portions of the spacer material layer are removed, while leaving portions of the spacer material layer on respective sidewalls of the dummy gate structures 322 and respective sidewalls of the fins 304. The remaining portions of the spacer material layer on sidewalls of the dummy gate structures 322 are denoted as gate spacers 326 as illustrated in FIG. 29A, and the remaining portions of the spacer material layer on sidewalls of the fins 304 are denoted as fin spacers 328 as illustrated in FIG. 29B.

The gate spacers 326 and fin spacers 328 may be formed of a nitride (e.g., silicon nitride), silicon oxynitride, silicon carbide, silicon carbonitride, the like, or a combination thereof, and may be deposited using, e.g., CVD, ALD or other suitable deposition processes. In some embodiments where the spacer material layer includes silicon nitride, the patterning of the silicon nitride layer includes a dry etching using CH₂F₂ as an etchant. In other embodiments in which the spacer material layer includes a silicon oxide layer and a silicon nitride layer, the patterning of the spacer material layer includes a dry etching using CH₂F₂ as an etchant to pattern silicon nitride, followed by a dry etching using CF₄ as an etchant to pattern the silicon oxide layer. The patterning includes an anisotropic effect, so that the horizontal portions of the spacer material layer are removed, while some vertical portions on the sidewalls of the dummy gate structures 322 remain to form gate spacers 326, and some vertical portions of the spacer material layer on the sidewalls of fins 304 remain to form fin spacers 328. In some embodiments, the process conditions for etching the spacer material layer are controlled to allow top ends of the fins 304 higher than top ends of the fins spacers 328.

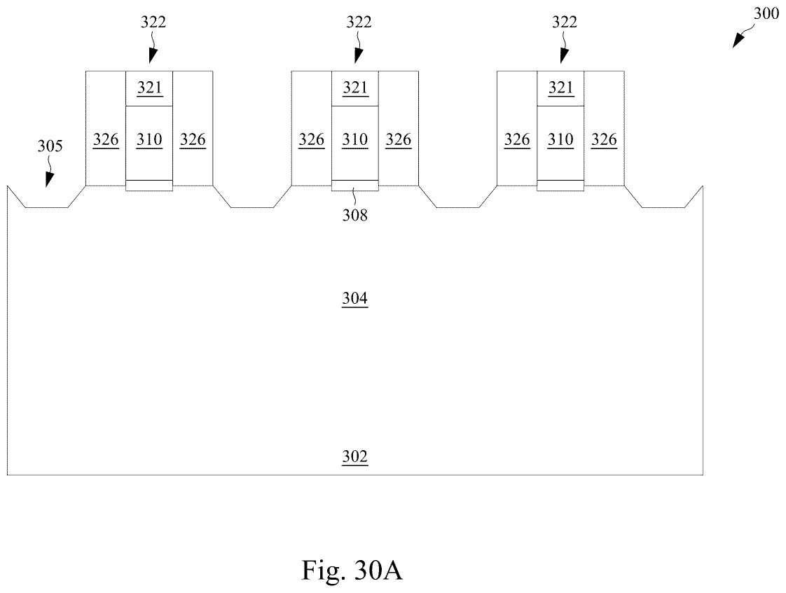

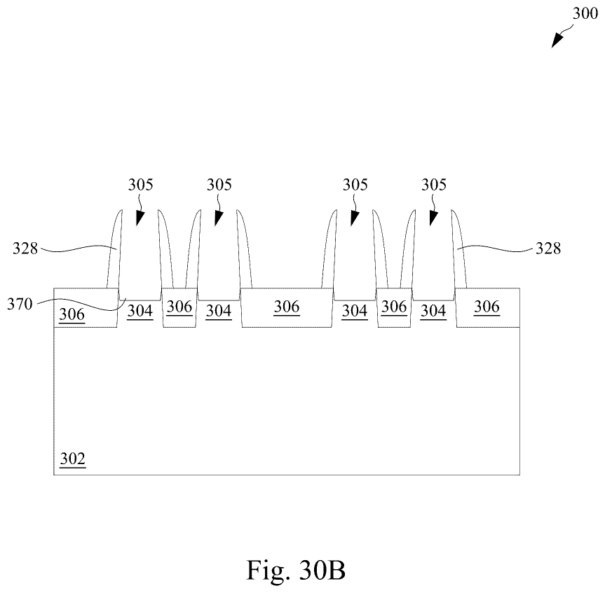

FIGS. 30A and 30B illustrate the cross-section view of the FinFET device 300 along cross-sections D-D′ and F-F′ in a fabrication stage following the processing of FIGS. 29A-29C. The exposed portions of the fins 304 are etched to form recesses 305 in the fins.

In some embodiments, the exposed portions of the fins 304 can be recessed using suitable selective etching processing that attacks the semiconductor fin 304, but hardly attacks the gate spacers 326, fin spacers 328, and the top masks 321 of the dummy gate structures 322. For example, recessing the semiconductor fins 304 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the semiconductor fins 304 at a faster etch rate than it etches the gate spacers 326, fin spacers 328, and the top masks 321 of the dummy gate structures 322. In some other embodiments, recessing the semiconductor fins 304 may be performed by a wet chemical etch, such as ammonium peroxide mixture (APM), NH₄OH, tetramethylammonium hydroxide (TMAH), combinations thereof, or the like, which etches the semiconductor fins 304 at a faster etch rate than it etches the gate spacers 326, fin spacers 328, and the top masks 321 of the dummy gate structures 322. In some other embodiments, recessing the semiconductor fins 304 may be performed by a combination of a dry chemical etch and a wet chemical etch.

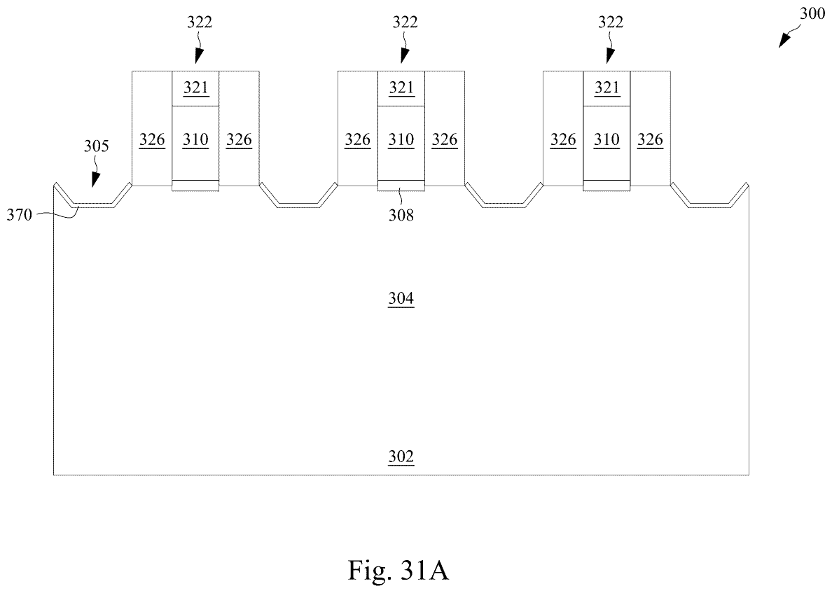

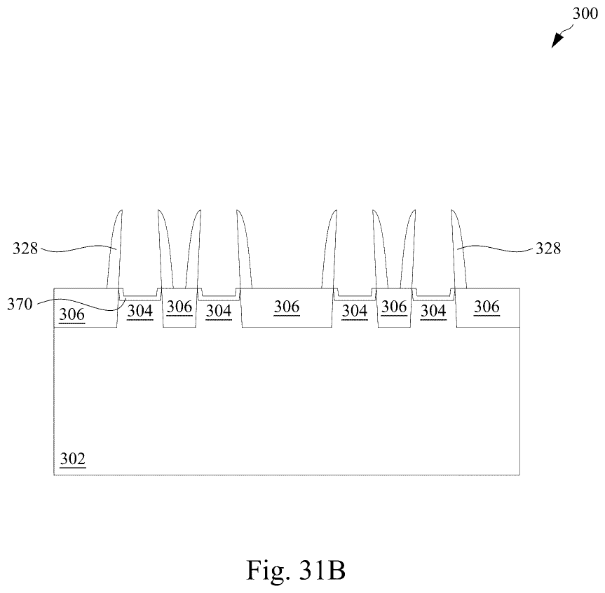

Reference is made to FIGS. 31A and 31B to illustrate forming a plurality of anti-doping epitaxial layers 370 on structures as shown in FIGS. 30A and 30B, respectively. The anti-doping epitaxial layers 370 are formed along the exposed bottom surfaces of the recesses 305 and thus raised from the sidewalls of the gate spacer 326 and the inner sidewalls of the fin spacers 328. In FIGS. 31A and 31B, the anti-doping epitaxial layers 370 have U-shaped profiles between the gate spacers 326 and between the fin spacers 328.

In one or more embodiments of the present disclosure, a plurality of undoped semiconductor layers is deposited over the exposed bottom surfaces of the source/drain recess 305 by a deposition process such as CVD process, and the undoped semiconductor layers may be implanted with dopants to form the anti-doping epitaxial layers 370, followed by an anneal. In some embodiments, the anti-doping epitaxial layers 370 may be in-situ or ex-situ doped during growth. In some embodiments, material of the undoped semiconductor layers used for forming the anti-doping epitaxial layers 370 may include acceptable material appropriate for GAA-FETs such as silicon or silicon germanium.

The anti-doping epitaxial layers 370 may be used to prevent unintended dopant diffusion from the formed source/drain regions 312 to the substrate 302. Therefore, the anti-doping epitaxial layers 370 may have different conductivity type from the subsequently formed source/drain regions.

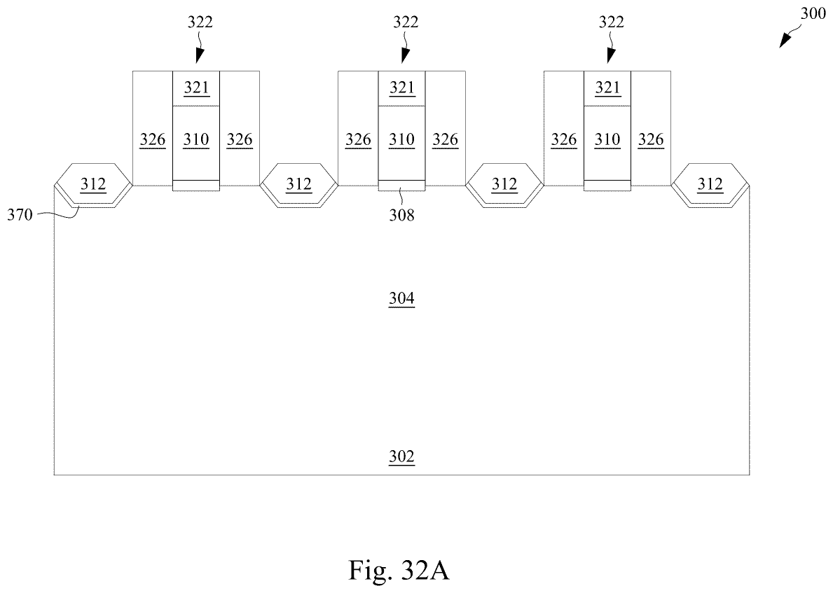

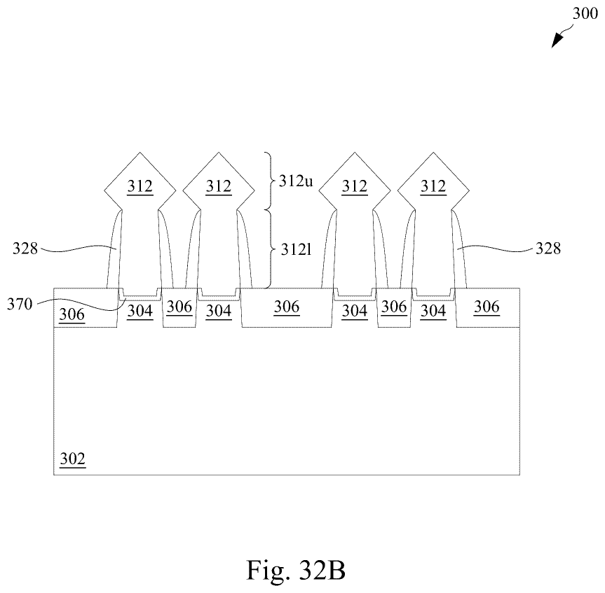

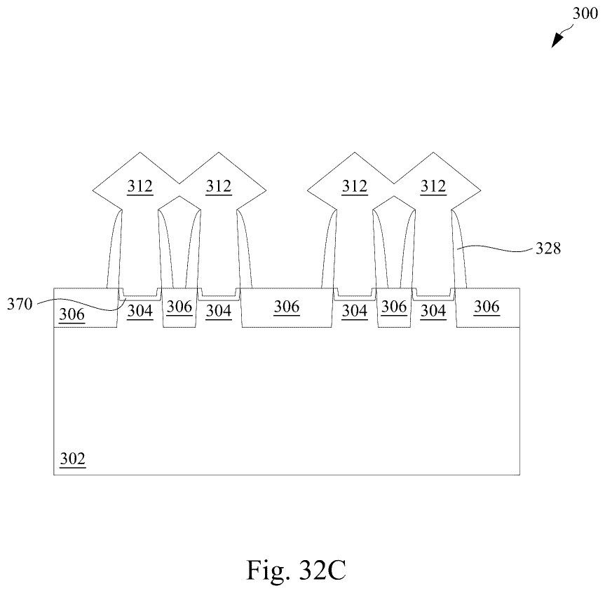

Reference is made to FIGS. 32A through 32C. Once the anti-doping epitaxial layers 370 are formed in the recess 305, epitaxial structures 312 are formed in the source/drain recesses in the fins 304 and over the anti-doping epitaxial layers 370 to serve as source/drain regions 312 of transistors, by using one or more epitaxy or epitaxial (epi) processes that provides one or more epitaxial materials on the semiconductor fins 304. During the epitaxial growth process, the gate spacers 326 and fin spacers 328 limit the one or more epitaxial materials to exposed regions in the fins 304. As illustrated in FIG. 32A, the epitaxial source/drain regions 312 may have surfaces raised from respective surfaces of the fins 304 (e.g. raised above the non-recessed portions of the fins 304) and may have facets. Since the source/drain regions 312 may formed along the anti-doping epitaxial layers 370 raised from the gate spacers 326 and the fin spacers 328, the anti-doping epitaxial layers 370 may have stepped profile along top ends of the anti-doping epitaxial layers 370.

In some embodiments, the source/drain regions 312 epitaxially grown on adjacent fins 304 do not merge together and remain separate source/drain regions 312, as illustrated in FIG. 32B. In some other embodiments, the source/drain regions 312 epitaxially grown on the adjacent fins 304 may merge to form a continuous epitaxial source/drain region 312, as illustrated in FIG. 32C.

In some embodiments, as illustrated in FIGS. 32B and 32C, the epitaxial material may be confined by the fin recess between corresponding fin spacers 328 and thus may have straight vertical or sloping sidewalls in between the fin spacers 328. Once the epitaxial material is grown to above the fin spacers 328, the epitaxial material will not be limited by the fin spacers 328 and thus form facets to have diamond shape. As a result, when viewed in a cross-sectional view taken along a direction perpendicular to longitudinal axes of fins 304 (e.g., FIG. 32B or 32C), each source/drain region 312 grown from a fin 304 has a lower portion 3121 confined between a corresponding pair of fin spacers 328, and an upper portion 312u free of confinement by the corresponding pair of fin spacers 328. The upper portion 312u has a different cross-sectional profile than the lower portion 3121. In particular, the upper portion 312u of each source/drain region 312 has a diamond cross-sectional profile, and the lower portion 3121 of each source/drain region 312 has a rectangular cross-sectional profile or a trapezoidal cross-sectional profile.

In some embodiments, the lattice constants of the epitaxy material of source/drain regions 312 are different from the lattice constant of the semiconductor fins 304, so that the channel regions in the fins 304 and between the source/drain regions 312 can be strained or stressed by the epitaxial material across the anti-doping epitaxial layers 370 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor fins 304. In some embodiments of the present disclosure, formation of the anti-doping epitaxial layers 370 and the epitaxial source/drain regions 312 can be in-situ achieved, i.e., realized in the same processing chamber. In some other embodiments, the anti-doping epitaxial layers 370 are can be ex-situ formed with respect to the epitaxial source/drain regions 312.

In some embodiments, the source/drain regions 312 may include Ge, Si, GaAs, AlGaAs, SiGe, GaAsP, SiP, or other suitable material. The source/drain regions 312 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 312 are not in-situ doped, an implantation process (i.e., a junction implant process) is performed to dope the source/drain epitaxial structures 312. In some exemplary embodiments, the source/drain epitaxial structures 312 in an n-type transistor include SiP, while those in a p-type include GeSnB and/or SiGeSnB. In embodiments with different device types, a mask, such as a photoresist, may be formed over n-type device regions, while exposing p-type device regions and p-type epitaxial structures may be formed on the exposed fins 304 in the p-type device regions. The mask may then be removed. Subsequently, a mask, such as a photoresist, may be formed over the p-type device region while exposing the n-type device regions and n-type epitaxial structures may be formed on the exposed fins 304 in the n-type device region. The mask may then be removed.

Once the source/drain regions 312 are formed, an annealing process can be performed to activate the p-type dopants or n-type dopants in the source/drain regions 312. The annealing process may be, for example, a rapid thermal anneal (RTA), a laser anneal, a millisecond thermal annealing (MSA) process or the like.

In some embodiments, once the formed source/drain regions 312 formed over the anti-doping epitaxial layers 370 is p-type epitaxial material, the anti-doping epitaxial layers 370 are selected to have n-type dopant such as P or As, so that the anti-doping epitaxial layers 370 may include is SiP or SiAs, for example. In some embodiments, the formed source/drain regions 312 formed over the anti-doping epitaxial layers 370 is n-type epitaxial material, the anti-doping epitaxial layers 370 are selected to have p-type dopant such as B, so that the anti-doping epitaxial layers 370 may include is SiB or Si₁Ge₁₋ₓB, wherein x is in a range between about 0% and about 100%. In some embodiments, the anti-doping epitaxial layers 370 may have an impurity concentration of between about 5×10¹⁹ atoms/cm³ and about 1×10²¹ atoms/cm³.

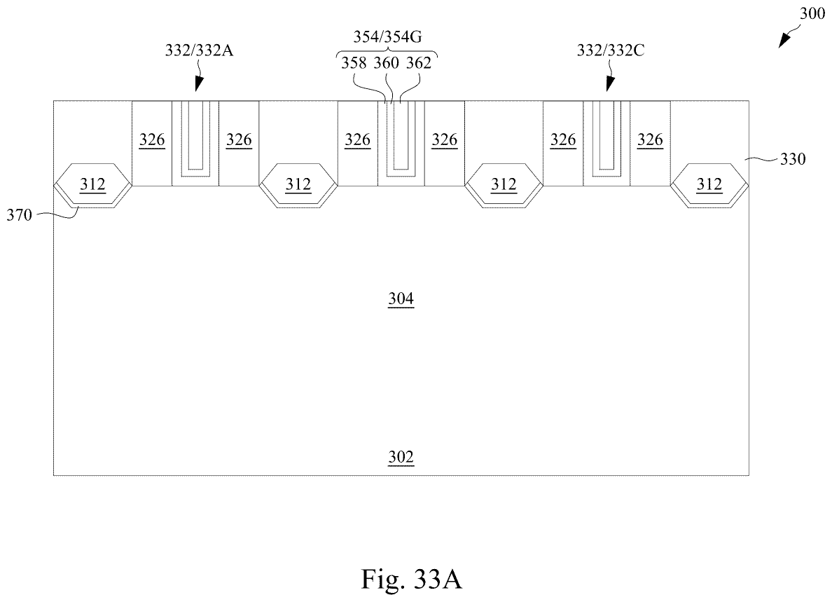

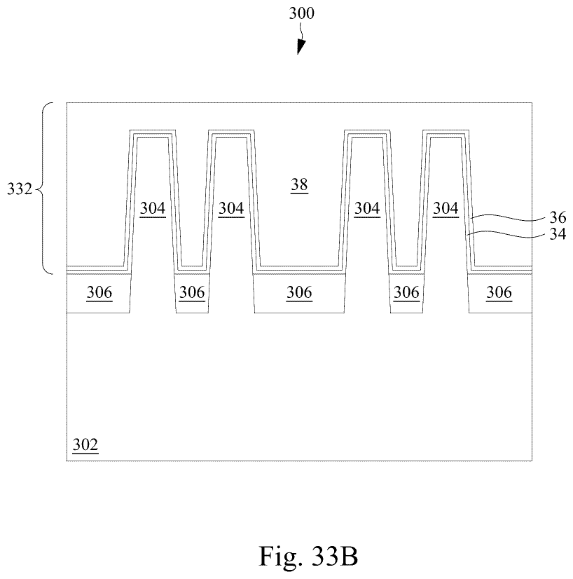

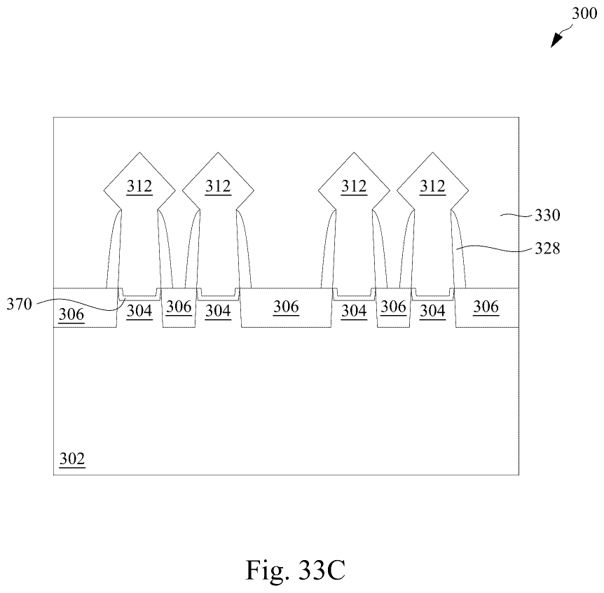

Reference is made to FIGS. 33A through 33C. As illustrated in FIG. 33A, a first interlayer dielectric (ILD) 330 is formed over the structure illustrated in FIG. 32A, and a gate-last process (sometimes referred to as replacement gate process) is performed. In a gate-last process, the gate 310 and the gate dielectric 308 (see FIG. 32A), which are considered dummy gate and dummy gate dielectric, respectively, are removed and replaced with an active gate and an active gate dielectric, which may be collectively referred to as a replacement gate.

In some embodiments, the first ILD 330 is formed of a dielectric material such as silicon oxide (SiO₂), phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD. A planarization process, such as CMP, may be performed to remove the mask 321 and to planarize the top surface of the first ILD 330, such that the top surface of the first ILD 330 is level with the top surface of the gate 310 after the CMP process. Therefore, after the CMP process, the top surface of the gate 310 is exposed, in the illustrated embodiments.

In accordance with some embodiments, the gate 310 and the gate dielectric 308 directly under the gate 310 are removed in an etching step(s), so that gate trenches each are formed between a corresponding pair of gate spacers 326. Each gate trench exposes a channel region of a respective fin 304. Each channel region may be disposed between neighboring pairs of epitaxial source/drain regions 312. During the dummy gate removal, the dummy gate dielectric layer 308 may be used as an etch stop layer when the dummy gate 310 is etched. The dummy gate dielectric layer 308 may then be removed after the removal of the dummy gate 310.

Next, replacement gate structures 332 are formed in respective gate trenches. The replacement gate structures 332 may be the final gates of FinFETs. The final gate structures each may be a high-k/metal gate stack, however other compositions are possible. In some embodiments, each of the replacement gate structures 332 forms the gate associated with the three-sides of a channel region provided by the fins 304. Stated another way, each of the replacement gate structures 332 wraps around channel regions of the fins 304 on three sides.

High-k/metal gate structures 332 are formed in the gate trenches by forming a gate dielectric layer 34, a work function metal layer 36, and a gate electrode 38 successively in each of the gate trenches. As illustrated in FIG. 32A, the gate dielectric layer 34 is deposited conformally in the gate trenches. The work function metal layer 36 is formed conformally over the gate dielectric layer 34, and the gate electrode 38 fills the recesses. The gate dielectric layer 34 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (˜3.9). The work function metal layer 36 and/or gate electrode 38 used within high-k/metal gate structures 332 may include a metal, metal alloy, or metal silicide. Formation of the high-k/metal gate structures 332 may include multiple deposition processes to form various gate materials, one or more liner layers, followed by one or more CMP processes to remove excessive gate materials. After the one or more CMP processes are complete, gate materials remain in the gate trenches to serve as high-k/metal gate structures 332.

In some embodiments, the interfacial layer of the gate dielectric layer 34 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 34 may include hafnium oxide (HfO₂). Alternatively, the gate dielectric layer 34 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 36 may include work function metals to provide a suitable work function for the high-k/metal gate structures 332. For an n-type FinFET, the work function metal layer 36 may include one or more n-type work function metals (N-metal). The n-type work function metals may exemplarily include, but are not limited to, titanium aluminide (TiAl), titanium aluminium nitride (TiAIN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer 3 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the gate electrode 38 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAIN, or other suitable materials.

Three metal gate structures 332 (e.g., 332A, 332B, and 332C) are illustrated in the example of FIG. 33A. However, more or less than three metal gate structures 332 may be used to form the FinFET device 300, as skilled artisans readily appreciate.

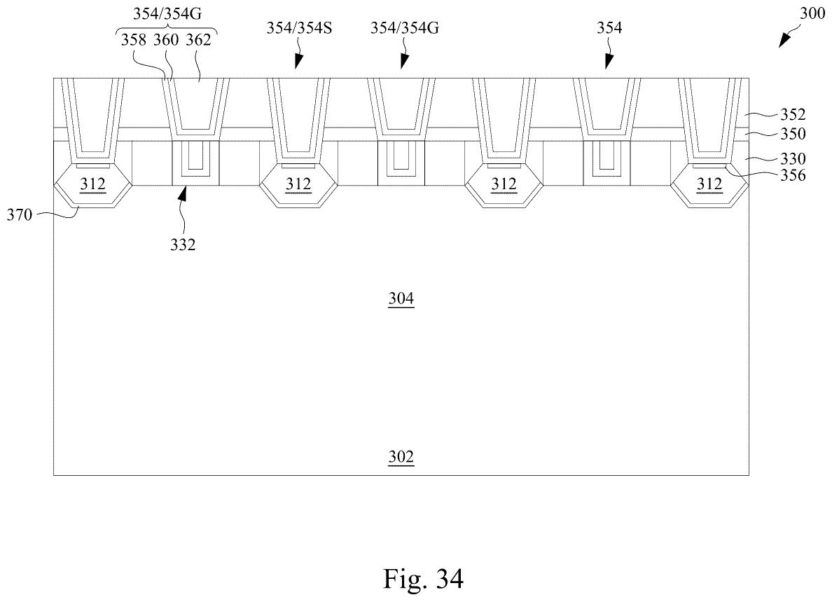

Reference is made to FIG. 34. A contact etch stop layer (CESL) 350 is formed over the metal gate structures 332 and the gate isolation plug 348, and a second ILD 352 is formed over the CESL 350. The CESL 350 may be formed by a PECVD process and/or other suitable deposition processes. In some embodiments, the CESL 350 is a silicon nitride layer and/or other suitable materials having a different etch selectivity than the second ILD 352. In some embodiments, the second ILD layer 352 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 350. In certain embodiments, the second ILD 352 is formed of silicon oxide (SiOₓ). The second ILD 352 may be deposited by a PECVD process or other suitable deposition technique.

Next, contacts 354 (e.g., gate contacts 354G and source/drain contacts 354S) are formed over and electrically coupled to the metal gate structures 332 or source/drain regions 312. To form the contacts 354, contact openings are formed through the second ILD 352, the CESL 350, and/or the first ILD 330 to expose the source/drain regions 312 and the metal gate structures 332, and the contact openings are then filled with electrically conductive material(s) to form the contacts 354. In some embodiments, silicide regions 356 are formed over the source/drain regions 312 before the contact openings are filled. Details of forming the contacts 354 are discussed hereinafter.

In some embodiments, silicide regions 356 are formed over the source/drain regions 312. Silicide regions 356 may be formed by first depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the source/drain regions 312, then performing a thermal anneal process to form the silicide regions 356. The un-reacted portions of the deposited metal are then removed, e.g., by an etching process. Although regions 356 are referred to as silicide regions, regions 356 may also be germanide regions, or silicon germanide regions (e.g., regions comprising silicide and germanide).

Next, a barrier layer 358 is formed lining sidewalls and bottoms of the contact openings, over the silicide regions 356, and over the upper surface of the second ILD 352. The barrier layer 358 may comprise titanium nitride, tantalum nitride, titanium, tantalum, the like, and may be formed by ALD, PVD, CVD, or other suitable deposition method. Next, a seed layer 360 is formed over the barrier layer 358. The seed layer 360 may be deposited by PVD, ALD or CVD, and may be formed of tungsten, copper, or copper alloys, although other suitable methods and materials may alternatively be used. Once the seed layer 360 has been formed, a conductive material 362 may be formed on the seed layer 360, filling and overfilling the contact openings. The conductive material 362 may comprise tungsten, although other suitable materials such as aluminum, copper, tungsten nitride, rhuthenium, silver, gold, rhodium, molybdenum, nickel, cobalt, cadmium, zinc, alloys of these, combinations thereof, and the like, may alternatively be utilized. Any suitable deposition method, such as PVD, CVD, ALD, plating (e.g., electroplating), and reflow, may be used to form the conductive material 362.

Once the contact openings have been filled, excess portions of the barrier layer 358, seed layer 360, and conductive material 362 outside of the contact openings may be removed through a planarization process such as CMP, although any suitable removal process may be used. Contacts 354 are thus formed in the contact openings. The contacts 354 are illustrated in a single cross-section as an example, the contacts 354 could be in different cross-sections.

According to one or more embodiments of the present disclosure, a method of forming a semiconductor device includes a number of operations. Source/drain recesses are formed on opposing side of a channel region over a substrate. Anti-doping epitaxial layers are formed over the source/drain recesses, wherein the anti-doping epitaxial layers have a first conductivity type. Source/drain epitaxial regions are formed over the anti-doping epitaxial layers, wherein the source/drain epitaxial regions have a second conductivity type different from the first conductivity type. A gate structure is formed over the channel regions. In one or more embodiments of the present disclosure, the method further includes forming undoped semiconductor layers over the source/drain recesses before the anti-doping epitaxial layers are formed, wherein the anti-doping epitaxial layers are formed over the undoped semiconductor layers. In one or more embodiments of the present disclosure, the method further includes etching sidewalls of the channel region exposed from the source/drain recesses, wherein the anti-doping epitaxial layers are formed along the etched sidewalls of the channel region. In one or more embodiments of the present disclosure, a first impurity concentration of the anti-doping epitaxial layers is less than an impurity concentration of the source/drain epitaxial regions. In one or more embodiments of the present disclosure, a thickness of each of the anti-doping epitaxial layers is less than 5 nm. In one or more embodiments of the present disclosure, the first conductivity type of the anti-doping epitaxial layers is n-type, and the second conductivity type of the source/drain epitaxial regions is p-type. In one or more embodiments of the present disclosure, the first conductivity type of the anti-doping epitaxial layers is p-type, and the second conductivity type of the source/drain epitaxial regions is n-type.

According to one or more embodiments of the present disclosure, a method of forming a semiconductor device includes a number of operations. A multilayer stack is epitaxially grown over a substrate, wherein the multilayer stack comprises first semiconductor layers and second semiconductor layers alternating with the first semiconductor layers. A source/drain recess is etched in the multilayer stack. Sidewalls of the first semiconductor layers are laterally recessed. Inner spacers are formed over the recessed sidewalls of the first semiconductor layers. Anti-doping epitaxial layers are formed over sidewalls of the second semiconductor layers. A source/drain epitaxial structure is formed in the source/drain recess and over the anti-doping epitaxial layer. The first semiconductor layers are replaced with a gate structure wrapping around the second semiconductor layers. In one or more embodiments of the present disclosure, the anti-doping epitaxial layers are offset from the inner spacers, and the source/drain epitaxial structure comprises a plurality of protruding portions extending between the anti-doping epitaxial layers. In one or more embodiments of the present disclosure, the method further includes forming a plurality of recesses on sidewalls of the second semiconductor layers, wherein the anti-doping epitaxial layers are formed along the recesses on the sidewalls of the second semiconductor layers. In some embodiments, a depth of each of the recesses on the sidewalls of the second semiconductor layers is less than a thickness of each of the inner spacers. In one or more embodiments of the present disclosure, an impurity concentration of the anti-doping epitaxial layers is less than a second impurity concentration of the source/drain epitaxial structure. In one or more embodiments of the present disclosure, a thickness of each of the anti-doping epitaxial layers is less than 5 nm.

According to one or more embodiments of the present disclosure, a semiconductor device includes a channel region, a gate structure, source/drain epitaxial regions and anti-doping epitaxial layers. The channel region is over a substrate. The gate structure is over the channel region. The source/drain epitaxial regions are on opposing sides of the channel regions. The anti-doping epitaxial layers are between the source/drain epitaxial regions and the channel region. A conductivity type of the anti-doping epitaxial layers is different from a conductivity type of the source/drain epitaxial region. In one or more embodiments of the present disclosure, the semiconductor device further includes a dopant-free semiconductor layer between the channel region and the anti-doping epitaxial layers. In one or more embodiments of the present disclosure, an impurity concentration of the anti-doping epitaxial layers is less than an impurity concentration of the source/drain epitaxial regions. In one or more embodiments of the present disclosure, the channel regions comprise a plurality of nanostructures arranged over the substrate. The anti-doping epitaxial layers are between sidewalls of the nanostructures and the source/drain epitaxial regions. In some embodiments, the semiconductor device further includes a plurality of spacers over the gate structure and between the nanostructures. The anti-doping epitaxial layers are protruded from the spacers. In some embodiments, the source/drain epitaxial regions include a plurality of protruding portions extending between the anti-doping epitaxial layers. In some embodiments, a thickness of each of the anti-doping epitaxial layers is less than a thickness of each of the spacers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming source/drain recesses on opposing side of a channel region over a substrate;
forming anti-doping epitaxial layers over the source/drain recesses, wherein the anti-doping epitaxial layers have a first conductivity type;
forming source/drain epitaxial regions over the anti-doping epitaxial layers, wherein the source/drain epitaxial regions have a second conductivity type different from the first conductivity type; and
forming a gate structure over the channel region.

2. The method of claim 1, further comprising:
forming undoped semiconductor layers over the source/drain recesses before forming the anti-doping epitaxial layers, wherein the anti-doping epitaxial layers are formed over the undoped semiconductor layers.

3. The method of claim 1, further comprising:
etching sidewalls of the channel region exposed from the source/drain recesses, wherein the anti-doping epitaxial layers are formed along the etched sidewalls of the channel region.

4. The method of claim 1, wherein an impurity concentration of the anti-doping epitaxial layers is less than an impurity concentration of the source/drain epitaxial regions.

5. The method of claim 1, wherein a thickness of each of the anti-doping epitaxial layers is less than 5 nm.

6. The method of claim 1, wherein the first conductivity type of the anti-doping epitaxial layers is n-type, and the second conductivity type of the source/drain epitaxial regions is p-type.

7. The method of claim 1, wherein the first conductivity type of the anti-doping epitaxial layers is p-type, and the second conductivity type of the source/drain epitaxial regions is n-type.

8. A method comprising:
epitaxially growing a multilayer stack over a substrate, wherein the multilayer stack comprising first semiconductor layers and second semiconductor layers alternating with the first semiconductor layers;
etching a source/drain recess in the multilayer stack;
laterally recessing sidewalls of the first semiconductor layers;
forming inner spacers over the recessed sidewalls of the first semiconductor layers;
forming anti-doping epitaxial layers over sidewalls of the second semiconductor layers;
forming a source/drain epitaxial structure in the source/drain recess and over the anti-doping epitaxial layers; and
replacing the first semiconductor layers with a gate structure wrapping around the second semiconductor layers.

9. The method of claim 8, wherein the anti-doping epitaxial layers are offset from the inner spacers, and the source/drain epitaxial structure comprises a plurality of protruding portions extending between the anti-doping epitaxial layers.

10. The method of claim 8, further comprising:
forming a plurality of recesses on sidewalls of the second semiconductor layers, wherein the anti-doping epitaxial layers are formed along the recesses on the sidewalls of the second semiconductor layers.

11. The method of claim 10, wherein a depth of each of the recesses on the sidewalls of the second semiconductor layers is less than a thickness of each of the inner spacers.

12. The method of claim 8, wherein an impurity concentration of the anti-doping epitaxial layers is less than an impurity concentration of the source/drain epitaxial structure.

13. The method of claim 8, wherein a thickness of each of the anti-doping epitaxial layers is less than 5 nm.

14. A semiconductor device comprising:
a channel region over a substrate;
a gate structure over the channel region;
source/drain epitaxial regions on opposing sides of the channel regions; and
anti-doping epitaxial layers between the source/drain epitaxial regions and the channel region, wherein a conductivity type of the anti-doping epitaxial layers is different from a conductivity type of the source/drain epitaxial regions.

15. The semiconductor device of claim 14, further comprising:
a dopant-free semiconductor layer between the channel region and the anti-doping epitaxial layers.

16. The semiconductor device of claim 14, wherein an impurity concentration of the anti-doping epitaxial layers is less than an impurity concentration of the source/drain epitaxial regions.

17. The semiconductor device of claim 14, wherein the channel regions comprise a plurality of nanostructures arranged over the substrate, and the anti-doping epitaxial layers are between sidewalls of the nanostructures and the source/drain epitaxial regions.

18. The semiconductor device of claim 17, further comprising:
a plurality of spacers over the gate structure and between the nanostructures, wherein the anti-doping epitaxial layers are protruded from the spacers.

19. The semiconductor device of claim 18, wherein the source/drain epitaxial regions comprises:
a plurality of protruding portions extending between the anti-doping epitaxial layers.

20. The semiconductor device of claim 18, wherein a thickness of each of the anti-doping epitaxial layers is less than a thickness of each of the spacers.
